(19) United States
(12) Patent Application Publication
(10) Pub. No.: US 2023/0395613 A1
(43) Pub. Date: Dec. 7, 2023

(54) WIRING SUBSTRATE AND DISPLAY DEVICE

(71) Applicant: Sharp Display Technology Corporation, Kameyama City (JP)

(72) Inventors: Ryohki ITOH, Kameyama City (JP); Hiroto AKIYAMA, Kameyama City (JP)

(21) Appl. No.: 18/204,758

(22) Filed: Jun. 1, 2023

(30) Foreign Application Priority Data
Jun. 2, 2022 (JP) 2022-090131

(51) Int. Cl. H01L 27/12; G02F 1/1362; G02F 1/1343; G02F 1/1368; G02F 1/1333

(52) U.S. Cl. CPC H01L 27/1244; G02F 1/136295; G02F 1/134372; G02F 1/136204; G02F 1/13439; G02F 1/13338; G02F 1/1368

(57) ABSTRACT

A wiring substrate includes a first terminal, a second terminal disposed side by side at intervals from the first terminal in a first direction, a third terminal disposed side by side at intervals from the first terminal in the first direction on a side opposite to the second terminal, a first wiring positioned between the first terminal and the second terminal, a second wiring connected to the first terminal and the third terminal, and an insulating portion disposed on an upper layer side of the first terminal, the second terminal, the third terminal, the first wiring, and the second wiring, in which the third terminal is disposed at a position where an interval between the third terminal and the first terminal is longer than any of an interval between the first wiring and the first terminal, and an interval between the first wiring and the second terminal.

### BACKGROUND

### 1. Field

A technique disclosed in the present specification relates to a wiring substrate and a display device.

### 2. Description of the Related Art

In the related art, as an example of a wiring substrate used in a liquid crystal panel, one described in Japanese Unexamined Patent Application Publication No. 2012-99721 below is known. Japanese Unexamined Patent Application Publication No. 2012-99721 describes a thin film transistor (TFT) array substrate as a wiring substrate. The TFT array substrate described in Japanese Unexamined Patent Application Publication No. 2012-99721 includes a TFT, a source electrode, a drain electrode, a transparent conductive film pattern directly superimposed on any of metal patterns formed in the same layer and made of the same material as the source electrode and the drain electrode, and an upper layer insulating film covering the gate insulating film including the transparent conductive film pattern, in which the transparent conductive film pattern formed at least in a picture-frame area is formed without covering a pattern end surface of the source electrode, the drain electrode, or the metal pattern.

At an end portion of the TFT array substrate described in Japanese Unexamined Patent Application Publication No. 2012-99721, an external connection terminal is connected to a mounted scanning signal drive circuit. On the other hand, in most of a mounting area of the scanning signal drive circuit, lead-out wiring is disposed between the external connection terminals adjacent to each other, but in a part of the mounting area of the scanning signal drive circuit, the lead-out wiring is not disposed between the external connection terminals adjacent to each other. An interval between two external connection terminals adjacent to each other without the lead-out wiring interposed therebetween is normally longer than an interval between the external connection terminal and the lead-out wiring. When the TFT array substrate is heated during mounting of the scanning signal drive circuit, thermal expansion and thermal contraction occur in the insulating portion formed on the upper layer side of the external connection terminal and the lead-out wiring. As a result, on a portion of the insulating portion existing between two external connection terminals adjacent to each other without the lead-out wiring interposed therebetween, when compared to a portion existing between the external connection terminal and the lead-out wiring, there is a possibility that a large stress due to expansion and contraction may act and the stress may cause local peeling. When peeling occurs on a portion of the insulating film existing between two external connection terminals adjacent to each other without the lead-out wiring interposed therebetween, there is a possibility that the two external connection terminals adjacent to each other may be short-circuited. When two external connection terminals adjacent to each other are short-circuited, there is concern that an electrical defect may occur in the TFT array substrate.

The technique described in the present specification is completed based on the circumstances as described above, and it is desirable to avoid an electrical defect caused by a short circuit between a first terminal and a third terminal.

### SUMMARY

(1) According to an aspect of a technique described in the present specification, there is provided a wiring substrate including a first terminal, a second terminal disposed side by side at intervals from the first terminal in a first direction, a third terminal disposed side by side at intervals from the first terminal in the first direction on a side opposite to the second terminal, a first wiring positioned between the first terminal and the second terminal and that extends along a second direction intersecting the first direction, a second wiring connected to the first terminal and the third terminal, and an insulating portion disposed on an upper layer side of the first terminal, the second terminal, the third terminal, the first wiring, and the second wiring, in which the third terminal is disposed at a position where an interval between the third terminal and the first terminal is longer than any of an interval between the first wiring and the first terminal, and an interval between the first wiring and the second terminal.

(2) According to another aspect of a technique described in the present specification, there is provided a wiring substrate including a first terminal, a second terminal disposed side by side at intervals from the first terminal in a first direction, a third terminal disposed side by side at intervals from the first terminal in the first direction on a side opposite to the second terminal, a first wiring positioned between the first terminal and the second terminal and that extends along a second direction intersecting the first direction, and an insulating portion disposed on an upper layer side of the first terminal, the second terminal, the third terminal, and the first wiring, in which the third terminal is disposed at a position where an interval between the third terminal and the first terminal is longer than any of an interval between the first wiring and the first terminal, and an interval between the first wiring and the second terminal, mounted components are mounted on positions of the wiring substrate that overlap with at least the first terminal, the second terminal, and the third terminal, a potential is supplied from the mounted component to the first terminal and the second terminal, and a potential is not supplied from the mounted component to the third terminal.

(3) According to still another aspect of a technique described in the present specification, there is provided a display device including the wiring substrate according to above (1) or (2), and a counter substrate disposed to face the wiring substrate.

### BRIEF DESCRIPTION OF THE DRAWINGS

FIG. 1 is a plan view of a liquid crystal panel, a driver, a flexible substrate, and the like that constitute a liquid crystal display device according to a first embodiment;

FIG. 2 is a cross-sectional view of the liquid crystal panel, the driver, the flexible substrate, and the like;

FIG. 3 is a circuit diagram showing an electrical configuration of an array substrate that constitutes the liquid crystal panel;

FIG. 4 is a cross-sectional view of a display area of the liquid crystal panel;

FIG. 5 is a plan view showing an arrangement area of a driver on the array substrate;

FIG. 6 is a cross-sectional view on the array substrate and the driver taken along the line vi-vi in FIG. 5;

FIG. 7 is a cross-sectional view on the array substrate taken along the line vii-vii in FIG. 5;

FIG. 8 is a cross-sectional view on the array substrate and the driver taken along the line viii-viii in FIG. 5;

FIG. 9 is a plan view showing an arrangement area of a driver of an array substrate according to a second embodiment;

FIG. 10 is a plan view showing an arrangement area of a driver of an array substrate according to a third embodiment;

FIG. 11 is a plan view showing an arrangement area of a driver of an array substrate according to a fourth embodiment;

FIG. 12 is a plan view showing an arrangement area of a driver of an array substrate according to a fifth embodiment;

FIG. 13 is a plan view showing an arrangement area of a driver of an array substrate according to a sixth embodiment;

FIG. 14 is a plan view showing an arrangement area of a driver of an array substrate according to a seventh embodiment;

FIG. 15 is a plan view showing an arrangement area of a driver of an array substrate according to an eighth embodiment;

FIG. 16 is a plan view showing an arrangement area of a driver of an array substrate according to a ninth embodiment;

FIG. 17 is a plan view showing an arrangement area of a driver of an array substrate according to a tenth embodiment;

and

FIG. 18 is a plan view showing an arrangement area of a driver of an array substrate according to an eleventh embodiment.

### DESCRIPTION OF THE EMBODIMENTS

### First Embodiment

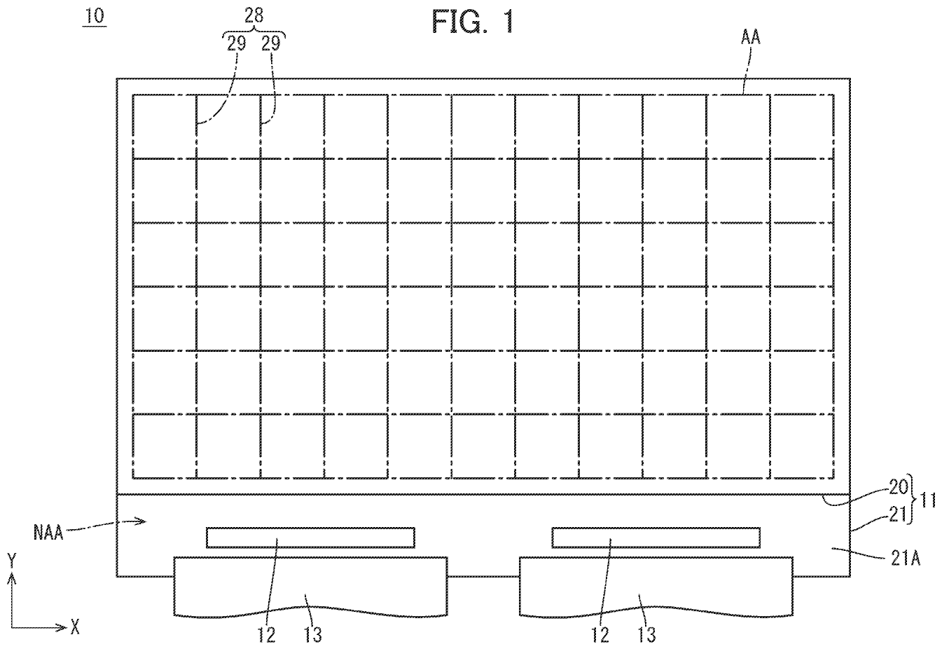

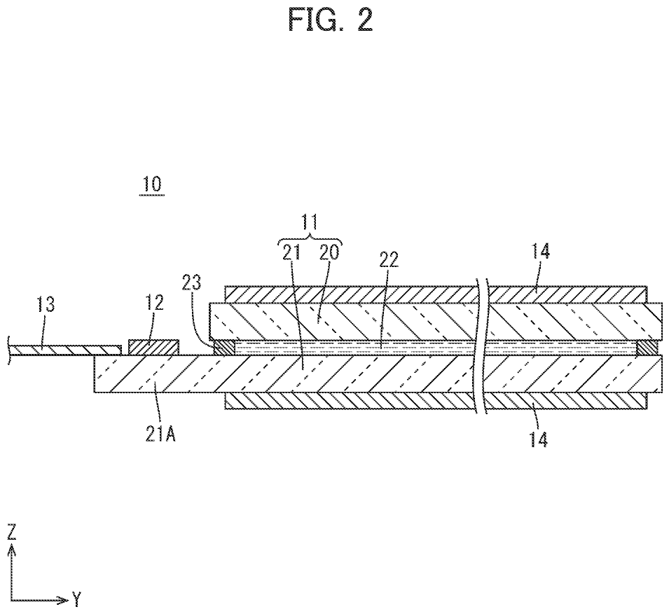

The first embodiment will be described with reference to FIGS. 1 to 8. In the present embodiment, a liquid crystal display device 10 including a display function and a touch panel function (position input function) is exemplified. The X-axis, Y-axis, and Z-axis are shown in a part of each drawing, and the direction of each axis is drawn in the direction shown in each drawing. An upper side of FIGS. 2, 4, 6, 7, and 8 is defined as a front side, and a lower side of the same drawing is defined as a rear side.

As shown in FIG. 1, the liquid crystal display device 10 includes at least a horizontally long rectangular liquid crystal panel (display device, display panel) 11 capable of displaying images, and a backlight device (illumination device) serving as an external light source that irradiates the liquid crystal panel 11 with light used for display. The backlight device is disposed on the rear side (rear surface side) of the liquid crystal panel 11, and has a light source (for example, light emitting diode (LED)) that emits white light, an optical member that converts the light from the light source into planar light by applying an optical effect, and the like. A central portion of the screen of the liquid crystal panel 11 is defined as a display area AA in which an image is displayed. On the other hand, a picture-frame-shaped peripheral portion surrounding the display area AA on the screen of the liquid crystal panel 11 is defined as a non-display area NAA in which no image is displayed.

The liquid crystal panel 11 will be described in detail with reference to FIG. 2, in addition to FIG. 1. As shown in FIGS. 1 and 2, the liquid crystal panel 11 is formed by attaching a pair of substrates 20 and 21. The front side (front surface side) of the pair of substrates 20 and 21 is defined as a counter substrate (CF substrate) 20 and the rear side (rear surface side) is defined as an array substrate (wiring substrate, active matrix substrate) 21. Both the counter substrate 20 and the array substrate 21 are formed by laminating various films on the inner surface side of a glass substrate. A liquid crystal layer (medium layer) 22 containing a liquid crystal molecule, which is a substance whose optical characteristics change with the application of an electric field, is interposed and disposed between the pair of substrates 20 and 21. A seal portion 23 for sealing the liquid crystal layer 22 is interposed between the outer peripheral end portions of the pair of substrates 20 and 21. The seal portion 23 is formed in a square frame shape (endless ring) so as to surround the liquid crystal layer 22. A polarizing plate 14 is attached to each of the outer surface sides of both substrates 20 and 21.

The counter substrate 20 has a short side dimension shorter than that of the array substrate 21, as shown in FIGS. 1 and 2. The counter substrate 20 is attached to the array substrate 21 so that one end portion thereof in the short side direction (Y-axis direction) is aligned. Therefore, the other end portion of the array substrate 21 in the short side direction is defined as an exposed portion 21A that protrudes laterally from the counter substrate 20 and is exposed. The entire area of the exposed portion 21A is a non-display area NAA, and a driver (mounted component, signal supply portion) 12 and a flexible substrate 13 for supplying various signals related to the display function and the touch panel function, which will be described later, are mounted.

The driver 12 includes an LSI chip having a drive circuit inside. The driver 12 is mounted on the exposed portion 21A on the array substrate 21 by chip on glass (COG). The driver 12 processes various signals transmitted by the flexible substrate 13. As shown in FIGS. 1 and 2, the driver 12 is disposed adjacent to one side of the display area AA in the Y-axis direction, and is sandwiched between the flexible substrate 13 and the display area AA, which will be described below. The driver 12 has a horizontally long rectangular shape in a plan view. Two drivers 12 are disposed side by side at positions at intervals in the X-axis direction (first direction). The driver 12 supplies various signals (for example, image signal, touch signal, and the like) to the wiring (specifically, source wiring 27 and touch wiring 30 which will be described later) of the display area AA.

The flexible substrate 13 has a configuration in which a large number of wiring patterns are formed on a base material made of an insulating and flexible synthetic resin material (for example, polyimide resin or the like). As shown in FIGS. 1 and 2, the flexible substrate 13 has one end connected to the exposed portion 21A on the array substrate 21 and the other end connected to an external circuit substrate. The flexible substrate 13 is connected to the end portion of the exposed portion 21A on the side opposite to the display area AA side with respect to the driver 12 in the Y-axis direction. Two flexible substrates 13 are disposed side by side at positions at intervals in the X-axis direction, and have a positional relationship disposed side by side at intervals from the two drivers 12 in the Y-axis direction (second direction).

The liquid crystal panel 11 according to the present embodiment has both a display function of displaying an image and a touch panel function of detecting the position (input position) where the user inputs based on the displayed image. The liquid crystal panel 11 is integrated (in-cell) with a touch panel pattern for exhibiting the touch panel function. This touch panel pattern is defined as a so-called projection electrostatic capacitance system, and a detection system is defined as a self-capacitance system. As shown in FIG. 1, the touch panel pattern is configured to include a plurality of touch electrodes (position detection electrodes) 29 disposed side by side in a matrix shape in a plate surface of the liquid crystal panel 11. The touch electrodes 29 are disposed in the display area AA of the liquid crystal panel 11. Therefore, the display area AA of the liquid crystal panel 11 substantially coincides with a touch area (position input area) where the input position can be detected, and the non-display area NAA substantially coincides with a non-touch area (non-position input area) where the input position does not be detected. When a finger (position input member), which is a conductor, is brought close to the surface (display surface) of the liquid crystal panel 11 with to perform position input based on the image in the display area AA of the liquid crystal panel 11 visually recognized by the user, an electrostatic capacitance is formed between the finger and the touch electrode 29. As a result, the electrostatic capacitance detected by the touch electrode 29 near the finger changes as the finger is brought close and becomes different from that of the touch electrode 29 far from the finger, so that input position can be detected based on this fact. In addition to the illustration in FIG. 1, the specific number of the touch electrodes 29 to be installed can be appropriately changed. The touch electrode 29 has a substantially rectangular shape in a plan view, and the dimension of one side is approximately several millimeters. Therefore, the touch electrodes 29 are much larger than a pixel described later in a plan view size, and are disposed in a range spanning a plurality of pixels in the X-axis direction and the Y-axis direction.

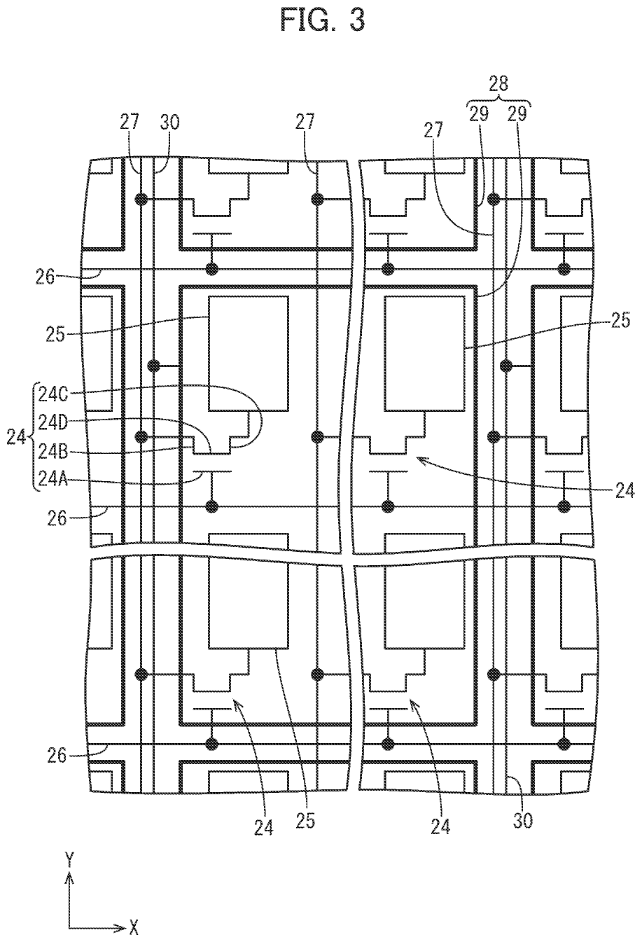

Next, the configuration of the display area AA on the array substrate 21 will be described with reference to FIG. 3. At least TFTs (thin film transistor, switching element) 24 and pixel electrodes 25 are provided on the inner surface side of the display area AA on the array substrate 21, as shown in FIG. 3. A plurality of the TFTs 24 and a plurality of the pixel electrodes 25 are provided in a matrix shape (rows and rows) side by side at intervals along the X-axis direction and the Y-axis direction. Gate wiring (scanning wiring) 26 and source wiring (image wiring, signal wiring) 27 are disposed to be orthogonal to (intersect) each other around these TFTs 24 and the pixel electrodes 25. The gate wiring 26 extends along the X-axis direction. The source wiring 27 extends along the Y-axis direction. The TFT 24 includes a gate electrode 24A connected to the gate wiring 26, a source electrode 24B connected to the source wiring 27, a drain electrode 24C connected to the pixel electrode 25, and a semiconductor portion 24D made of a semiconductor material and connected to the source electrode 24B and the drain electrode 24C. The TFT 24 is driven based on a scanning signal supplied to the gate electrode 24A through the gate wiring 26. As a result, the potential associated with the image signal (data signal) supplied from the driver 12 to the source electrode 24B through the source wiring 27 is supplied to the drain electrode 24C via the semiconductor portion 24D. As a result, the pixel electrode 25 is charged to the potential associated with the image signal. The pixel electrode 25 is disposed in an area surrounded by the gate wiring 26 and the source wiring 27, and has a substantially rectangular planar shape, for example.

A common electrode 28 is formed on the inner surface side of the display area AA on the array substrate 21 so as to overlap with all the pixel electrodes 25, as shown in FIG. 3. The common electrode 28 extends over substantially the entire area of the display area AA. A plurality of slits extending along the long side direction of each pixel electrode 25 are opened in a portion of the common electrode 28 overlapping with each pixel electrode 25. In FIG. 3, illustration of the slits is omitted. When the pixel electrode 25 is charged and a potential difference occurs between the pixel electrode 25 and the common electrode 28 that overlap with each other, a fringe electric field (oblique electric field) is generated that includes a component in the normal direction to the plate surface of the array substrate 21, in addition to the component along the plate surface of the array substrate 21, between the opening edge of the slit and the pixel electrode 25. Therefore, by utilizing this fringe electric field, an alignment state of the liquid crystal molecules contained in the liquid crystal layer 22 can be controlled. That is, the operation mode of the liquid crystal panel 11 according to the present embodiment is a fringe field switching (FFS) mode. The common electrode 28 constitutes the touch electrode 29 described above. The common electrode 28 has a partition slit that partitions adjacent touch electrodes 29 in addition to the slits described above. The common electrode 28 is configured to include a plurality of touch electrodes 29 divided into a grid pattern by the partition slits and electrically independent of each other.

A plurality of touch wirings (position detection wirings) 30 connected to a plurality of touch electrodes 29 are provided on the inner surface side of the display area AA on the array substrate 21, as shown in FIG. 3. The plurality of touch wirings 30 are individually connected to the plurality of touch electrodes 29. A common signal (reference potential signal) related to the display function and a touch signal (position detection signal) related to the touch function are supplied from the driver 12 to the touch wiring 30 at different timings (in a time division manner). The timing at which the common signal is supplied from the driver 12 to the touch wiring 30 is a display period, and the timing at which the touch signal is supplied from the driver 12 to the touch wiring 30 is a sensing period (position detection period). Since the common signal is supplied to all the touch wirings 30 during the display period, all the touch electrodes 29 have a reference potential and function as the common electrode 28. As described above, since the liquid crystal display device 10 according to the present embodiment has a display function and a touch panel function and has high definition, a plurality of drivers 12 are mounted and the functions of the plurality of drivers 12 are enhanced.

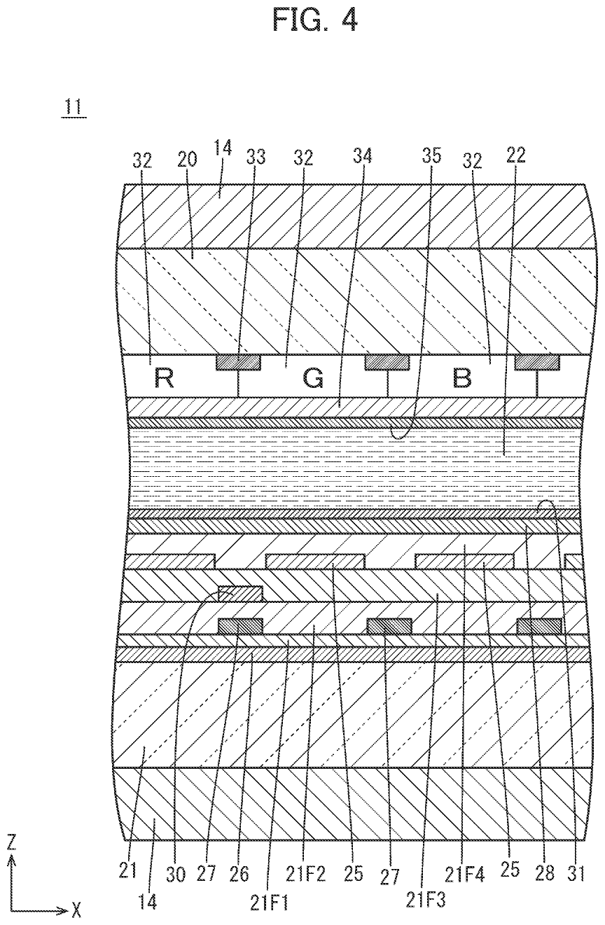

Here, various films laminated on the inner surface side of the array substrate 21 will be described with reference to FIG. 4. As shown in FIG. 4, on the array substrate 21, a first metal film, a gate insulating film (insulating portion, first insulating film) 21F1, a semiconductor film, a second metal film, a first interlayer insulating film (insulating portion, second insulating film) 21F2, a third metal film, a second interlayer insulating film (insulating portion, third insulating film) 21F3, a first transparent electrode film, a third interlayer insulating film (fourth insulating film) 21F4, a second transparent electrode film, and an alignment film 31 are laminated in this order from the lower layer side (glass substrate side). Each of the first metal film, the second metal film, and the third metal film has conductivity and light shielding properties by being a single layer film made of one type of metal material selected from copper, titanium, aluminum, molybdenum, tungsten, and the like, or a laminated film made of different types of metal materials or alloy. The first metal film constitutes the gate wiring 26, the gate electrode 24A of the TFT 24, and the like. The second metal film constitutes the source wiring 27, the source electrode 24B and the drain electrode 24C of the TFT 24, and the like. The third metal film constitutes the touch wiring 30 and the like. The semiconductor film is made of a thin film using, for example, an oxide semiconductor, amorphous silicon, or the like as a material, and constitutes the semiconductor portion 24D of the TFT 24 and the like. The first transparent electrode film and the second transparent electrode film are made of a transparent electrode material (for example, indium tin oxide (ITO) or indium zinc oxide (IZO)). The first transparent electrode film constitutes the pixel electrode 25 and the like. The second transparent electrode film constitutes the common electrode 28 (touch electrode 29) and the like. The alignment film 31 is made of polyamide or the like. The alignment film 31 is positioned on the innermost surface of the array substrate 21 and aligns the liquid crystal molecules contained in the liquid crystal layer 22.

Each of the gate insulating film 21F1, the first interlayer insulating film 21F2, the second interlayer insulating film 21F3, and the third interlayer insulating film 21F4 is made of inorganic materials such as silicon nitride (SiNₓ) and silicon oxide (SiO₂). The gate insulating film 21F1 keeps the first metal film on the lower layer side and the semiconductor film and the second metal film on the upper layer side in an insulated state. For example, an intersection portion of the gate wiring 26 made of the first metal film and the source wiring 27 made of the second metal film is kept in an insulated state by the gate insulating film 21F1. An overlapping portion of the gate electrode 24A made of the first metal film and the semiconductor portion 24D made of the semiconductor film is kept in an insulated state by the gate insulating film 21F1. The first interlayer insulating film 21F2 keeps the semiconductor film and the second metal film on the lower layer side and the third metal film on the upper layer side in an insulated state. The touch wiring 30 made of the third metal film is disposed to overlap with the source wiring 27 made of the second metal film via the first interlayer insulating film 21F2. The touch wiring 30 and the source wiring 27 overlapping with each other are kept in an insulated state by the first interlayer insulating film 21F2. The second interlayer insulating film 21F3 keeps the third metal film on the lower layer side and the first transparent electrode film on the upper layer side in an insulated state. For example, the touch wiring 30 made of the third metal film and the pixel electrode 25 made of the first transparent electrode film are kept in an insulated state by the second interlayer insulating film 21F3. The third interlayer insulating film 21F4 keeps the first transparent electrode film on the lower layer side and the second transparent electrode film on the upper layer side in an insulated state. For example, an overlapping portion of the pixel electrode 25 made of the first transparent electrode film F6 and the common electrode 28 (touch electrode 29) made of the second transparent electrode film F8 is kept in an insulated state by the third interlayer insulating film 21F4.

As shown in FIG. 4, color filters 32 of three colors of blue (B), green (G), and red (R) are provided in the display area AA on the inner surface side of the counter substrate 20. A plurality of color filters 32 having colors different from each other are disposed side by side so as to be adjacent to each other in the extending direction (X-axis direction) of the gate wiring 26. A plurality of color filters 32 having colors different from each other extend along the extending direction (Y-axis direction) of the source wiring 27. As described above, the plurality of color filters 32 having colors different from each other are arranged in stripes as a whole. These color filters 32 are disposed to overlap with each pixel electrode 25 on the side of the array substrate 21 in a plan view. In the liquid crystal panel 11, the color filters 32 of red, green, and blue disposed side by side along the X-axis direction, and the three pixel electrodes 25 facing the color filters 32 constitute three color pixel, respectively. In the liquid crystal panel 11, three color pixels of red, green, and blue adjacent to each other along the X-axis direction constitute display pixels capable of color display with a prescribed gray scale. A black matrix 33 is provided on the counter substrate 20 so as to partition the plurality of color filters 32 having colors different from each other. The black matrix 33 has a lattice shape in a plan view, and overlaps with a plurality of gate wirings 26 and a plurality of source wirings 27. An overcoat film 34 disposed in a solid pattern over substantially the entire area of the counter substrate 20 for planarization is provided on the upper layer side (liquid crystal layer 22 side) of the color filter 32. An alignment film 35 for aligning the liquid crystal molecules contained in the liquid crystal layer 22 is provided on the upper layer side of the overcoat film 34.

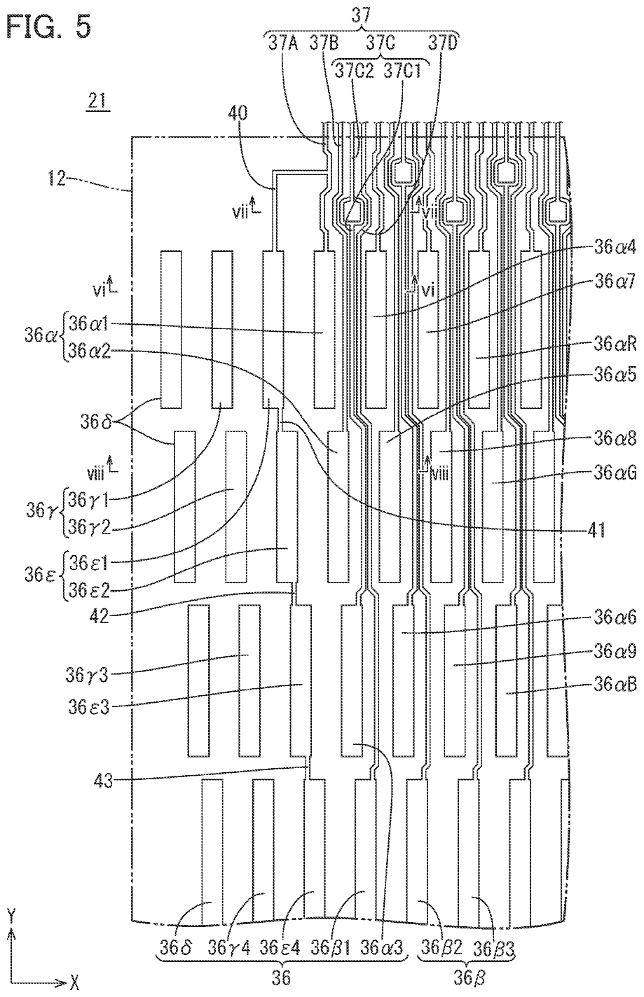

As shown in FIG. 1, wirings and terminals for supplying various signals (potentials) to the gate wiring 26, the source wiring 27, the common electrode 28, the touch wiring 30, and the like are provided on the inner surface side of the exposed portion 21A, which is the non-display area NAA on the array substrate 21. As shown in FIG. 5, a plurality of terminals 36 connected to the drivers 12 mounted on the exposed portion 21A are provided in an arrangement area (mounting area) of each driver 12 in the exposed portion 21A. A plurality of terminals connected to the flexible substrates 13 to be mounted are also provided in the arrangement areas of each of the flexible substrates 13 in the exposed portion 21A. In FIG. 5, the outer shape of the driver 12 mounted on the exposed portion 21A is shown by a chain double-dashed line.

As shown in FIG. 5, the terminal 36 has a vertically long rectangular shape in a plan view. The plurality of terminals 36 are disposed side by side at intervals in each of the X-axis direction (first direction) and the Y-axis direction (second direction). Each of the plurality of terminals 36 disposed side by side at intervals in the X-axis direction are aligned in the same position in the Y-axis direction, and all have equal intervals in the X-axis direction. That is, the plurality of terminals 36 are arranged at equal pitches in the X-axis direction. As a result, a defect in which adjacent terminals 36 are short-circuited due to film residue which may occur on each metal film during the manufacturing process of the array substrate 21 is unlikely to be generated. The interval between two terminals 36 adjacent to each other in the X-axis direction is longer than the width dimension of the terminals 36 (dimension in the X-axis direction), but smaller than the length dimension of the terminals 36 (dimension in the Y-axis direction). Each of the plurality of terminals 36 disposed side by side at intervals in the Y-axis direction are shifted in position in the X-axis direction, and all have equal intervals in the Y-axis direction. That is, the plurality of terminals 36 are disposed in a zigzag plane. Specifically, in the plurality of terminals 36 disposed side by side at intervals in the Y-axis direction, positions in the X-axis direction are shifted to the right side in FIG. 5 by approximately half the width dimension of the terminals 36. Specifically, of the two terminals 36 adjacent to each other in the Y-axis direction, the central position in the X-axis direction of the lower terminal 36 shown in FIG. 5 is shifted to the right side in FIG. 5 by approximately half the width dimension of the terminal 36 from the central position in the X-axis direction of the upper terminal 36 shown in FIG. 5. The interval between two terminals 36 adjacent to each other in the Y-axis direction is smaller than the width dimension of the terminal 36. FIG. 5 shows an aspect in which four terminals 36 are disposed side by side in the Y-axis direction.

As shown in FIG. 5, the plurality of terminals 36 includes at least a plurality of image signal terminals 36α to which image signals output from the driver 12 are input, a plurality of touch signal terminals 36β to which touch signals output from the driver 12 are input, a plurality of common signal terminals 36γ to which common signals output from the driver 12 are input, and a plurality of ground signal terminals 36σ to which ground signals output from the driver 12 are input. The ground signal terminals 36σ are positioned in the vicinity of the left end shown in FIG. 5 in the arrangement area of the driver 12, and a plurality (four in FIG. 5) of ground signal terminals 36σ are disposed side by side in a row at intervals in the Y-axis direction. The common signal terminal 36γ is disposed at a position adjacent to the ground signal terminal 36σ at intervals on the right side shown in FIG. 5 in the arrangement area of the driver 12. A plurality (four in FIG. 5) of the common signal terminals 36γ are disposed side by side in a row at intervals in the Y-axis direction. The image signal terminal 36α and the touch signal terminal 36β are disposed at positions at intervals from the common signal terminal 36γ on the right side shown in FIG. 5 in the arrangement area of the driver 12. The image signal terminals 36α are disposed side by side in one row of three at intervals in the Y-axis direction from the vicinity of the upper end shown in FIG. 5 in the arrangement area of the driver 12, and a plurality of rows are disposed side by side at intervals in the X-axis direction. Of the three image signal terminals 36α forming one row, the image signal terminal 36α positioned on the upper side in FIG. 5 is a red image signal terminal 36αR in which an image signal (hereinafter referred to as a red image signal) supplied to a pixel with a red color is input. Of the three image signal terminals 36α forming one row, the image signal terminal 36α positioned on the center in FIG. 5 is a green image signal terminal 36αG in which an image signal (hereinafter referred to as a green image signal) supplied to a pixel with a green color is input. Of the three image signal terminals 36α forming one row, the image signal terminal 36α positioned on the lower side in FIG. 5 is a blue image signal terminal 36αB in which an image signal (hereinafter referred to as a blue image signal) supplied to a pixel with a blue color is input. The touch signal terminals 36β are positioned in the vicinity of the lower end shown in FIG. 5 in the arrangement area of the driver 12, and a plurality of touch signal terminals 36β are disposed side by side at intervals in the X-axis direction. In addition to these, the terminals 36 include input terminals for inputting various signals to the driver 12 and the like.

As shown in FIG. 5, the lead-out wiring (first wiring) 37 of the source wiring 27 is connected to the image signal terminal 36α. The lead-out wiring 37 is routed from the display area AA to the arrangement area of the driver 12. One end portion (display area AA side) of the lead-out wiring 37 is connected to the end portion of the source wiring 27, and the other end portion (arrangement area side of the driver 12) is connected to the image signal terminal 36α. The lead-out wiring 37 is installed in the same number as the image signal terminals 36α. The lead-out wiring 37 extends normally along the Y-axis direction in the arrangement area of the driver 12. The plurality of lead-out wirings 37 include wirings that pass between two image signal terminals 36α adjacent to each other in the X-axis direction in the arrangement area of the driver 12. Specifically, the plurality of lead-out wirings 37 include first lead-out wiring 37A connected to the red image signal terminal 36αR, second lead-out wiring 37B connected to the green image signal terminal 36αG, third lead-out wiring 37C connected to the blue image signal terminal 36αB, and fourth lead-out wiring 37D connected to the touch signal terminal 36β. Among these wirings, the second lead-out wiring 37B, the third lead-out wiring 37C, and the fourth lead-out wiring 37D (first wiring) pass between two image signal terminals 36α adjacent to each other in the X-axis direction. The length of each lead-out wiring 37A to 37D in the arrangement area of the driver 12 differs according to the distance from the terminal 36 to be connected to the display area AA. Specifically, the length of the first lead-out wiring 37A is the shortest, and the length of the fourth lead-out wiring 37D is the longest.

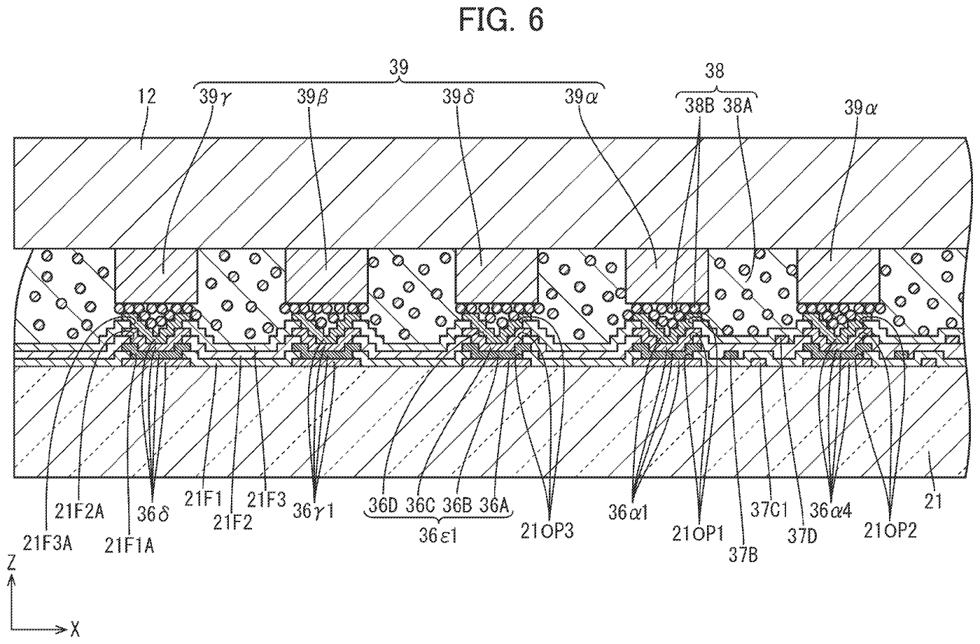

A cross-sectional configuration of the terminal 36 will be described with reference to FIG. 6. As shown in FIG. 6, the terminal 36 has a laminated structure of a first terminal configuration portion 36A made of a first metal film, a second terminal configuration portion 36B made of a second metal film, a third terminal configuration portion 36C made of a third metal film, and a fourth terminal configuration portion 36D made of a first transparent electrode film. An opening 21F1A is formed in the gate insulating film 21F1 disposed on the upper layer side of the first terminal configuration portion 36A at a position overlapping with the first terminal configuration portion 36A. The first terminal configuration portion 36A is exposed to the outside on the front side through the opening 21F1A and connected to the second terminal configuration portion 36B. An opening 21F2A is formed in the first interlayer insulating film 21F2 disposed on the upper layer side of the second terminal configuration portion 36B at a position overlapping with the second terminal configuration portion 36B. The second terminal configuration portion 36B is exposed to the outside on the front side through the opening 21F2A and connected to the third terminal configuration portion 36C. An opening 21F3A is formed in the second interlayer insulating film 21F3 disposed on the upper layer side of the third terminal configuration portion 36C at a position overlapping with the third terminal configuration portion 36C. The third terminal configuration portion 36C is exposed to the outside on the front side through the opening 21F3A and connected to the fourth terminal configuration portion 36D. Since the third interlayer insulating film 21F4 is not formed in the arrangement area of the driver 12, the entire fourth terminal configuration portion 36D is exposed to the outside on the front side. Since the fourth terminal configuration portion 36D positioned in the uppermost layer of the terminal 36 is made of the first transparent electrode film, corrosion is unlikely to occur in the first terminal configuration portion 36A, the second terminal configuration portion 36B, and the third terminal configuration portion 36C, which are positioned on the lower layer side of the fourth terminal configuration portion 36D and made of each metal film.

As shown in FIG. 6, bumps 39 provided on the driver 12 are connected to the terminals 36 having the cross-sectional configuration as described above via an anisotropic conductive film (ACF) 38. First, the anisotropic conductive film 38 will be described. The anisotropic conductive film 38 is formed by dispersing and blending a large number of conductive particles 38B in a binder 38A made of a thermosetting resin material. When mounting the drivers 12, the anisotropic conductive film 38 and the drivers 12 are set in the arrangement area of the driver 12 on the array substrate 21, and the drivers 12 are thermally compressed in this state. As a result, the terminals 36 on the array substrate 21 side and the bumps 39 on the driver 12 side are conducted via the conductive particles 38B.

The bump 39 will be described. The bump 39 is provided so as to protrude from the bottom surface of the driver 12 to the rear side, as shown in FIG. 6. The bump 39 is connected to a circuit provided inside the driver 12. A plurality of bumps 39 are disposed side by side on the bottom surface of the driver 12 at positions overlapping with each of the terminals 36 on the array substrate 21 side. A plurality of bumps 39 include at least a plurality of image signal bumps 39α that output image signals, a plurality of touch signal bumps that output touch signals, a plurality of common signal bumps 3913 that output common signals, and a plurality of ground signal bumps 39γ that outputs ground signals. The plurality of image signal bumps 39α are disposed at positions overlapping with each of the plurality of image signal terminals 36α, and are connected to each of the overlapping image signal terminals 36α via the anisotropic conductive film 38. The plurality of touch signal bumps are disposed at positions overlapping with each of the plurality of touch signal terminals 36β, and are connected to each of the overlapping touch signal terminals 36β via the anisotropic conductive film 38. The common signal bump 3913 is disposed at a position overlapping with each of the plurality of common signal terminals 36γ, and is connected to each of the overlapping common signal terminals 36γ via the anisotropic conductive film 38. The ground signal bump 39γ is disposed at a position overlapping each of the plurality of ground signal terminals 36σ, and is connected to each of the overlapping ground signal terminals 36σ via the anisotropic conductive film 38. In addition to these, the bumps 39 include an input bump connected to the input terminal on the array substrate 21 side.

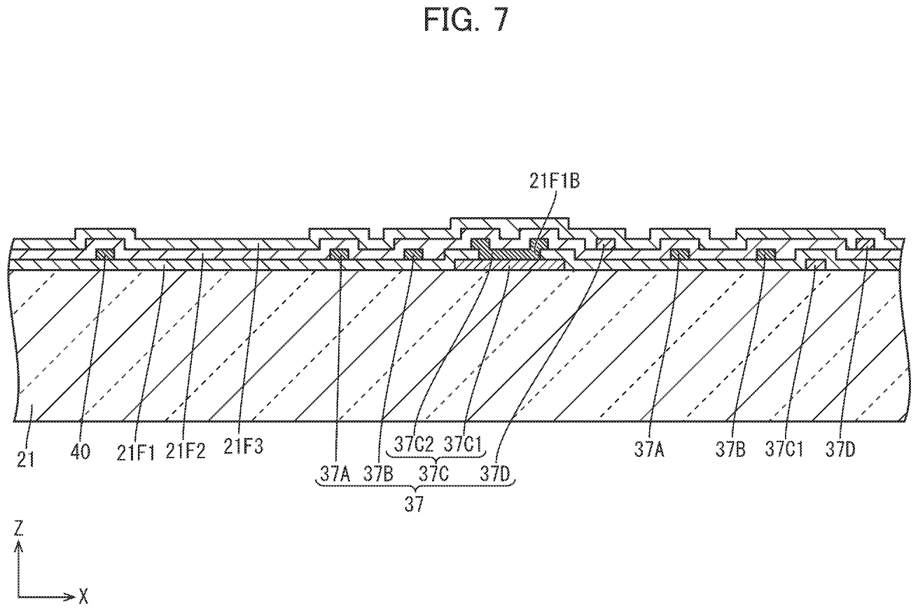

The lead-out wiring 37 will be described with reference to FIGS. 6 and 7. As shown in FIGS. 6 and 7, the lead-out wiring 37 is made of any metal film provided on the array substrate 21. Specifically, the first lead-out wiring 37A and the second lead-out wiring 37B included in the lead-out wiring 37 are both made of the same second metal film as those of the source wiring 27 and the second terminal configuration portion 36B. Therefore, the first lead-out wiring 37A and the second lead-out wiring 37B are directly connected to each of the source wirings 27 and each of the second terminal configuration portions 36B to be connected without a contact hole or the like interposed therebetween. The fourth lead-out wiring 37D is made of the same third metal film as that of the touch wiring 30. The fourth lead-out wiring 37D is directly connected to each of the touch wirings 30 to be connected and each of the third terminal configuration portions 36C without a contact hole or the like interposed therebetween. The third lead-out wiring 37C is configured to include a portion made of a first metal film (hereinafter referred to as a first wiring configuration portion 37C1) and a portion made of a second metal film (hereinafter referred to as a second wiring configuration portion 37C2). The first wiring configuration portion 37C1 has one end portion connected to the blue image signal terminal 36αB and the other end portion connected to the second wiring configuration portion 37C2. The first wiring configuration portion 37C1 extends along the Y-axis direction, and is disposed to be sandwiched between the second lead-out wiring 37B and the fourth lead-out wiring 37D in the X-axis direction between two image signal terminals 36α adjacent to each other in the X-axis direction. Since the gate insulating film 21F1 is interposed between the first wiring configuration portion 37C1 made of the first metal film and the second lead-out wiring 37B made of the second metal film, these arrangement intervals can be reduced. Since the gate insulating film 21F1 and the first interlayer insulating film 21F2 are interposed between the first wiring configuration portion 37C1 made of the first metal film and the fourth lead-out wiring 37D made of the third metal film, these arrangement intervals can be reduced. The second wiring configuration portion 37C2 has one end portion connected to the first wiring configuration portion 37C1 and the other end portion connected to the source wiring 27. The other end portion of the first wiring configuration portion 37C1 and one end portion of the second wiring configuration portion 37C2 are disposed to overlap with each other, and are connected to each other through a contact hole 21F1B opened in the gate insulating film 21F1 interposed therebetween.

The common signal terminal 36γ and the ground signal terminal 36σ according to the present embodiment are not connected to wirings existing on the array substrate 21. That is, the array substrate 21 according to the present embodiment operates using the common signal and the ground signal supplied from the mounted components other than the driver 12 such as the flexible substrate 13, and has specifications that do not use the common signal and the ground signal supplied from the driver 12. The reason why the driver 12 that supplies the common signal and the ground signal is used in the present embodiment is, for example, that the driver 12 that supplies the common signal and the ground signal is a general-purpose product and is inexpensive, which is preferable for reducing the procurement cost of components.

As shown in FIG. 5, the terminals 36 according to the present embodiment include a plurality of dummy terminals 36E. The dummy terminal 36E is positioned between the image signal terminal 36α and the common signal terminal 36γ in the X-axis direction in the arrangement area of the driver 12. Specifically, the dummy terminal 36E is adjacent to the common signal terminal 36γ at intervals on the right side shown in FIG. 5, and is disposed at a position adjacent to the image signal terminal 36α at intervals on the left side shown in FIG. 5. A plurality (four in FIG. 5) of the dummy terminals 36ε are disposed side by side in a row at intervals in the Y-axis direction. The bumps 39 provided in the driver 12 include a dummy bump 39σ disposed to overlap with the dummy terminal 36ε, as shown in FIG. 6. Similarly to the dummy terminals 36ε, a plurality of dummy bumps 390 are disposed side by side in a row at intervals in the Y-axis direction. The dummy bump 39σ is positioned between the image signal bump 39α and the common signal bump 3913 in the X-axis direction. The dummy terminal 36ε and the dummy bump 39σ that overlap with each other are connected to each other via the anisotropic conductive film 38. In the present embodiment, no signal is input from the dummy bump 39σ to the dummy terminal 36ε of the driver 12.

Hereinafter, among the plurality of dummy terminals 36ε disposed side by side in the Y-axis direction, the dummy terminal 36ε positioned at the upper end in FIG. 5 is defined as a first dummy terminal (third terminal) 36ε1, the dummy terminal 36ε positioned second from the upper end is defined as a second dummy terminal (sixth terminal) 36ε2, the dummy terminal 36ε positioned third from the upper end is defined as a third dummy terminal 36ε3, and the dummy terminal 36ε positioned fourth from the upper end is defined as a fourth dummy terminal 36ε4.

Among the plurality of image signal terminals 36α disposed side by side in the X-axis direction and the Y-axis direction, three image signal terminals 36α forming a row (row adjacent to the dummy terminal 36ε) positioned at the left end in FIG. 5 are defined as a first image signal terminal (first terminal) 36α1, a second image signal terminal (fourth terminal) 36α2, and a third image signal terminal 36α3 in order from the top in FIG. 5. Three image signal terminals 36α forming the second row from the left end in FIG. 5 are defined as a fourth image signal terminal (second terminal) 36α4, a fifth image signal terminal (fifth terminal) 36α5, and a sixth image signal terminal 36α6 in order from the top in FIG. 5. Three image signal terminals 36α forming the third row from the left end are defined as a seventh image signal terminal 36α7, an eighth image signal terminal 36α8, and a ninth image signal terminal 36α9 in order from the top in FIG. 5.

Among the plurality of touch signal terminals 36β disposed side by side in the X-axis direction, the touch signal terminal 36β positioned at the left end in FIG. 5 is defined as a first touch signal terminal 36β1, the touch signal terminal 36β positioned second from the left end is defined as a second touch signal terminal 36β2, the touch signal terminal 36β positioned third from the left end is defined as a third touch signal terminal 36β3. Among the plurality of common signal terminals 36γ disposed side by side in the Y-axis direction, the common signal terminal 36γ positioned at the upper end in FIG. 5 is defined as a first common signal terminal 36γ1, the common signal terminal 36γ positioned second from the upper end is defined as a second common signal terminal 36γ2, the common signal terminal 36γ positioned third from the upper end is defined as a third common signal terminal 36γ3, and the common signal terminal 36γ positioned fourth from the upper end is defined as a fourth common signal terminal 36γ4.

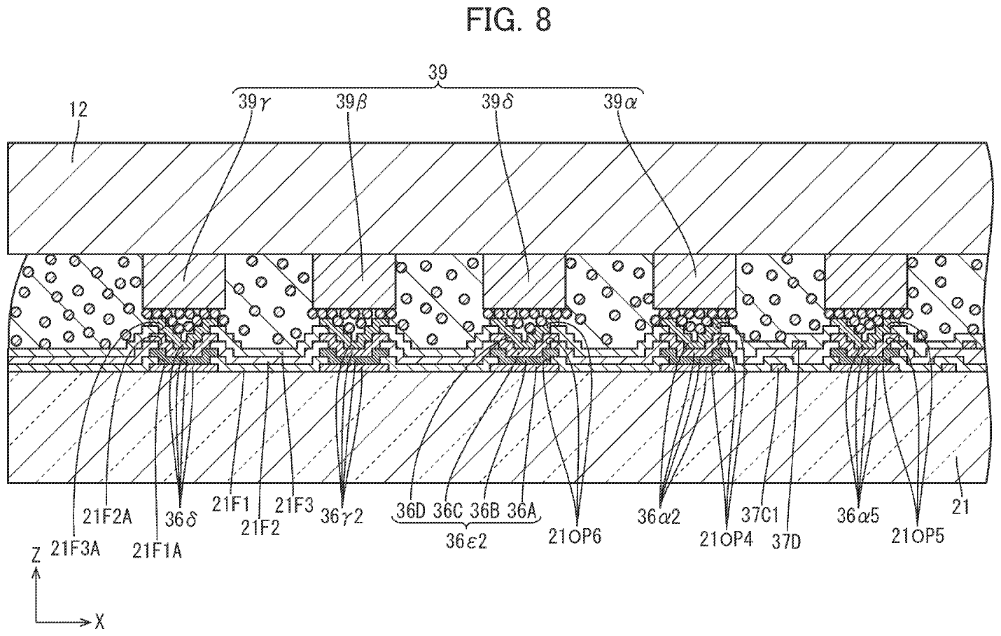

Each of the openings 21F1A to 21F3A of each of the insulating films 21F1 to 21F3 disposed to overlap with the first image signal terminal (first terminal) 36α1 is defined as a first opening 21OP1 (refer to FIG. 6). Similarly, each of the openings 21F1A to 21F3A of each of the insulating films 21F1 to 21F3 disposed to overlap with the fourth image signal terminal (second terminal) 36α4 is defined as a second opening 21OP2 (refer to FIG. 6). Similarly, each of the openings 21F1A to 21F3A of each of the insulating films 21F1 to 21F3 disposed to overlap with the first dummy terminal (third terminal) 36ε1 is defined as a third opening 21OP3 (refer to FIG. 6). Similarly, each of the openings 21F1A to 21F3A of each of the insulating films 21F1 to 21F3 disposed to overlap with the second image signal terminal (fourth terminal) 36α2 is defined as a fourth opening 21OP4 (refer to FIG. 8). Similarly, each of the openings 21F1A to 21F3A of each of the insulating films 21F1 to 21F3 disposed to overlap with the fifth image signal terminal (fifth terminal) 36α5 is defined as a fifth opening 21OP5 (refer to FIG. 8). Similarly, each of the openings 21F1A to 21F3A of each of the insulating films 21F1 to 21F3 disposed to overlap with the second dummy terminal (sixth terminal) 36ε2 is defined as a sixth opening 21OP6 (refer to FIG. 8).

As shown in FIGS. 5 and 7, the array substrate 21 according to the present embodiment is provided with a first connection wiring (second wiring) 40 connected to the first dummy terminal 36ε1 and the first lead-out wiring 37A. The first connection wiring 40 is indirectly connected to the first image signal terminal 36α1 via the first lead-out wiring 37A. The first dummy terminal 36ε1 is kept at the same potential as the first image signal terminal 36α1 by the first connection wiring 40 although signal is not input from the dummy bump 39σ of the driver 12. The first connection wiring 40 is made of the same second metal film as those of the first lead-out wiring 37A, the second terminal configuration portion 36B, and the like. Therefore, the first connection wiring 40 is directly connected to the second terminal configuration portion 36B and the first lead-out wiring 37A, which constitute the first dummy terminal 36ε1 to be connected, without a contact hole or the like interposed therebetween. The first dummy terminal 36ε1 is positioned between the first image signal terminal 36α1 and the first common signal terminal 36γ1 in the X-axis direction.

Incidentally, no lead-out wiring 37 is interposed between the first dummy terminal 36ε1 and the first image signal terminal 36α1 disposed at intervals in the X-axis direction, whereas the second lead-out wiring 37B, the third lead-out wiring 37C and the fourth lead-out wiring 37D are interposed between the first image signal terminal 36α1 and the fourth image signal terminal 36α4 disposed at intervals in the X-axis direction. Therefore, an interval between the first dummy terminal 36ε1 and the first image signal terminal 36α1 is longer than any of an interval between any of the second lead-out wiring 37B, the third lead-out wiring 37C, and the fourth lead-out wiring 37D and the first image signal terminal 36α1, and an interval between any of the second lead-out wiring 37B, the third lead-out wiring 37C, and the fourth lead-out wiring 37D and the fourth image signal terminal 36α4. Therefore, for example, even in a case where a film residue occurs on any of the metal films during the manufacture of the array substrate 21, a situation in which the first dummy terminal 36ε1 and the first image signal terminal 36α1 are short-circuited is unlikely to occur. Even in a case where the driver 12 is shifted when mounting the driver 12 on the array substrate 21, for example, connection failure is unlikely to occur.

In such a configuration, problems may occur when the gate insulating film 21F1, the first interlayer insulating film 21F2, and the second interlayer insulating film 21F3 thermally expand and thermally contract as the temperature environment of the array substrate 21 changes. Specifically, when the driver 12 is COG-mounted on the array substrate 21 via the anisotropic conductive film 38, since the driver 12 is pressurized at a high temperature (for example, 110° C. to 200° C.) for a predetermined time, the temperature environment of the array substrate 21 fluctuates greatly. As a result, among the gate insulating film 21F1, the first interlayer insulating film 21F2, and the second interlayer insulating film 21F3, a large stress due to expansion and contraction act on a portion existing between the first dummy terminal 36ε1 and the first image signal terminal 36α1, and peeling is likely to occur, compared to a portion existing between any of the second lead-out wiring 37B, the third lead-out wiring 37C, and the fourth lead-out wiring 37D and the first image signal terminal 36α1, or a portion existing between any of the second lead-out wiring 37B, the third lead-out wiring 37C, and the fourth lead-out wiring 37D and the fourth image signal terminal 36α4. In particular, the first image signal terminal 36α1 and the first dummy terminal 36ε1 according to the present embodiment are positioned closer to the end of the driver 12 than the second image signal terminal 36α2 and the second dummy terminal 36ε2. In such a configuration, among the gate insulating film 21F1, the first interlayer insulating film 21F2, and the second interlayer insulating film 21F3, since the portion existing between the first dummy terminal 36ε1 and the first image signal terminal 36α1 is positioned closer to the end of the driver 12, compared to a portion existing between the second dummy terminal 36ε2 and the second image signal terminal 36α2, a large stress acts due to thermal expansion and thermal contraction, and peeling tends to occur more easily. Among the gate insulating film 21F1, the first interlayer insulating film 21F2, and the second interlayer insulating film 21F3, when the portion existing between the first dummy terminal 36ε1 and the first image signal terminal 36α1 is peeled off, the first image signal terminal 36α1 and the first dummy terminal 36ε1 may be short-circuited. In addition to that fact, when an image signal whose polarity is inverted every frame is input to the image signal terminal 36α, electromigration may occur in the image signal terminal 36α over time. As a result, the first image signal terminal 36α1 and the first dummy terminal 36ε1 may be short-circuited. In this respect, the first connection wiring 40 according to the present embodiment is connected to the first image signal terminal 36α1 and the first dummy terminal 36ε1, so that the first image signal terminal 36α1 and the first dummy terminal 36ε1 are brought to the same potential in advance. Therefore, even in a case where the first image signal terminal 36α1 and the first dummy terminal 36ε1 are short-circuited due to peeling of the gate insulating film 21F1, the first interlayer insulating film 21F2, and the second interlayer insulating film 21F3, or electromigration of the first image signal terminal 36α1, it is possible to avoid an electrical defect in the array substrate 21 due to the short circuit.

As shown in FIG. 5, the array substrate 21 according to the present embodiment is provided with a second connection wiring (third wiring) 41 connected to the first dummy terminal 36ε1 and the second dummy terminal 36ε2. The second connection wiring 41 is made of the same second metal film as those of the second terminal configuration portion 36B and the like. Therefore, the second connection wiring 41 is directly connected to each of the second terminal configuration portions 36B, which constitutes the first dummy terminal 36ε1 and the second dummy terminal 36ε2 to be connected, without a contact hole or the like interposed therebetween. According to such a configuration, the first image signal terminal 36α1, the first dummy terminal 36ε1, and the second dummy terminal 36ε2 are brought to the same potential by the first connection wiring 40 and the second connection wiring 41. Therefore, even in a case where the first dummy terminal 36ε1 and the second dummy terminal 36ε2 are short-circuited, or the first image signal terminal 36α1 and the second dummy terminal 36ε2 are short-circuited due to peeling of the gate insulating film 21F1, the first interlayer insulating film 21F2, and the second interlayer insulating film 21F3, or electromigration of the first image signal terminal 36α1, it is possible to avoid an electrical defect in the array substrate 21 due to the short circuit.

As shown in FIG. 5, the array substrate 21 according to the present embodiment is provided with a third connection wiring 42 connected to the second dummy terminal 36ε2 and the third dummy terminal 36ε3, and a fourth connection wiring 43 connected to the third dummy terminal 36ε3 and the fourth dummy terminal 36ε4. The third connection wiring 42 and the fourth connection wiring 43 are made of the same second metal film as that of the second terminal configuration portion 36B. Therefore, the third connection wiring 42 and the fourth connection wiring 43 are directly connected to each of the second terminal configuration portions 36B, which constitutes the second dummy terminal 36ε2, the third dummy terminal 36ε3, and the fourth dummy terminal 36ε4 to be connected, without a contact hole or the like interposed therebetween. According to such a configuration, all the dummy terminals 36ε are brought to the same potential as that of the first image signal terminal 36α1. Therefore, even in a case where the second dummy terminal 36ε2 and the third dummy terminal 36ε3 are short-circuited, or the third dummy terminal 36ε3, and the fourth dummy terminal 36ε4 are short-circuited due to peeling of the gate insulating film 21F1, the first interlayer insulating film 21F2, and the second interlayer insulating film 21F3, it is possible to avoid an electrical defect in the array substrate 21 due to the short circuit.

As described above, the array substrate (wiring substrate) 21 of the present embodiment is provided with the first image signal terminal (first terminal) 36α1, the fourth image signal terminal (second terminal) 36α4 disposed side by side at intervals from the first image signal terminal 36α1 in the first direction, the first dummy terminal (third terminal) 36ε1 disposed side by side at interval from the first image signal terminal 36α1 on the side opposite to the fourth image signal terminal 36α4 in the first direction, the second lead-out wiring 37B, the third lead-out wiring 37C, and the fourth lead-out wiring 37D positioned between the first image signal terminal 36α1 and the fourth image signal terminal 36α4 and being the first wiring extending along the second direction intersecting the first direction, the first connection wiring (second wiring) 40 connected to the first image signal terminal 36α1 and the first dummy terminal 36ε1, and the gate insulating film 21F1, the first interlayer insulating film 21F2, and the second interlayer insulating film 21F3, which are insulating portions disposed on the upper layer side of the first image signal terminal 36α1, the fourth image signal terminal 36α4, the first dummy terminal 36ε1, the second lead-out wiring 37B, the third lead-out wiring 37C, and the fourth lead-out wiring 37D, which are the first wiring, and the first connection wiring 40, in which the first dummy terminal 36ε1 is disposed at a position where the interval between the first dummy terminal 36ε1 and the first image signal terminal 36α1 is longer than any of the interval between the second lead-out wiring 37B, the third lead-out wiring 37C, and the fourth lead-out wiring 37D, which are the first wirings, and the first image signal terminal 36α1, and the interval between the second lead-out wiring 37B, the third lead-out wiring 37C, and the fourth lead-out wiring 37D, which are the first wirings, and the fourth image signal terminal 36α4.

Since the interval between the first dummy terminal 36ε1 and the first image signal terminal 36α1 is longer than any of an interval between the second lead-out wiring 37B, the third lead-out wiring 37C, and the fourth lead-out wiring 37D, which are the first wirings, and the first image signal terminal 36α1, and the interval between the second lead-out wiring 37B, the third lead-out wiring 37C, and the fourth lead-out wiring 37D, which are the first wirings, and the fourth image signal terminal 36α4, for example, a situation in which the first dummy terminal 36ε1 and the first image signal terminal 36α1 are short-circuited is unlikely to occur during the manufacture of the array substrate 21. In such a configuration, when the gate insulating film 21F1, the first interlayer insulating film 21F2, and the second interlayer insulating film 21F3, which are the insulating portions, thermally expand and thermally contract as the temperature environment of the array substrate 21 changes, among the gate insulating film 21F1, the first interlayer insulating film 21F2, and the second interlayer insulating film 21F3, which are insulating portions, a large stress due to expansion and contraction acts on the portion existing between the first dummy terminal 36ε1 and the first image signal terminal 36α1, and peeling is likely to occurs, compared to a portion existing between the second lead-out wiring 37B, the third lead-out wiring 37C, and the fourth lead-out wiring 37D, which are the first wirings, and the first image signal terminal 36α1, or a portion existing between the second lead-out wiring 37B, the third lead-out wiring 37C, and the fourth lead-out wiring 37D, which are the first wirings, and the fourth image signal terminal 36α4. Among the gate insulating film 21F1, the first interlayer insulating film 21F2, and the second interlayer insulating film 21F3, which are insulating portions, when the portion existing between the first dummy terminal 36ε1 and the first image signal terminal 36α1 is peeled off, the first image signal terminal 36α1 and the first dummy terminal 36ε1 may be short-circuited. In that respect, since the first connection wiring 40 is connected to the first image signal terminal 36α1 and the first dummy terminal 36ε1, even in a case where the first image signal terminal 36α1 and the first dummy terminal 36ε1 are short-circuited due to peeling of the gate insulating film 21F1, the first interlayer insulating film 21F2, and the second interlayer insulating film 21F3, which are insulating portions, it is possible to avoid an electrical defect in the array substrate 21 due to the short circuit.

The second image signal terminal (fourth terminal) 36α2 disposed at intervals in the second direction from the first image signal terminal 36α1, the fifth image signal terminal (fifth terminal) 36α5 disposed at intervals in the second direction from the fourth image signal terminal 36α4 and disposed side by side at intervals in the first direction from the second image signal terminal 36α2, and the second dummy terminal (sixth terminal) 36ε2 disposed at intervals in the second direction from the first dummy terminal 36ε1 and disposed side by side at intervals in the first direction from the second image signal terminal 36α2 on the side opposite to the fifth image signal terminal 36α5 are provided. The driver (mounted component) 12 is mounted on the array substrate 21 at a position overlapping at least the first image signal terminal 36α1, the fourth image signal terminal 36α4, the first dummy terminal 36ε1, the second image signal terminal 36α2, the fifth image signal terminal 36α5, and the second dummy terminal 36ε2, and the first image signal terminal 36α1, the fourth image signal terminal 36α4, and the first dummy terminal 36ε1 are positioned closer to the end of the driver 12 from the second image signal terminal 36α2, the fifth image signal terminal 36α5, and the second dummy terminal 36ε2.

Among the gate insulating film 21F1, the first interlayer insulating film 21F2, and the second interlayer insulating film 21F3, which are insulating portions, since the portion existing between the first dummy terminal 36ε1 and the first image signal terminal 36α1 is positioned closer to the end of the driver 12, compared to a portion existing between the second dummy terminal 36ε2 and the second image signal terminal 36α2, a large stress acts due to thermal expansion and thermal contraction, and peeling tends to occur more easily. In that respect, since the first connection wiring 40 is connected to the first image signal terminal 36α1 and the first dummy terminal 36ε1, even in a case where the first image signal terminal 36α1 and the first dummy terminal 36ε1 are short-circuited due to peeling of the gate insulating film 21F1, the first interlayer insulating film 21F2, and the second interlayer insulating film 21F3, which are insulating portions, it is possible to avoid an electrical defect in the array substrate 21 due to the short circuit.

The second connection wiring (third wiring) 41 that connects the first dummy terminal 36ε1 and the second dummy terminal 36ε2 is provided. The first image signal terminal 36α1, the first dummy terminal 36ε1, and the second dummy terminal 36ε2 are brought to the same potential by the first connection wiring 40 and the second connection wiring 41. Therefore, even in a case where the first dummy terminal 36ε1 and the second dummy terminal 36ε2 are short-circuited, or the first image signal terminal 36α1 and the second dummy terminal 36ε2 are short-circuited due to peeling of the gate insulating film 21F1, the first interlayer insulating film 21F2, and the second interlayer insulating film 21F3, which are insulating portions, it is possible to avoid an electrical defect in the array substrate 21 due to the short circuit.

The TFT (thin film transistor) 24, the pixel electrode 25 connected to the TFT 24, the common electrode 28 disposed so as to overlap with the pixel electrode 25, and a common electrode 28 including a plurality of touch electrodes (position detection electrodes) 29, and the touch wiring (position detection wiring) 30 connected to the touch electrode 29 are provided. The TFT 24 includes the gate electrode 24A, the semiconductor portion 24D disposed so as to overlap with the gate electrode 24A, the source electrode 24B in contact with a part of the semiconductor portion 24D, and the drain electrode 24C disposed at intervals from the source electrode 24B and in contact with a part of the semiconductor portion 24D. The gate electrode 24A is made of a first metal film, the semiconductor portion 24D is made of a semiconductor film, the source electrode 24B is made of a second metal film, the drain electrode 24C is made of a portion of the second metal film different from the source electrode 24B, the touch wiring 30 is made of a third metal film, the pixel electrode is made of a first transparent electrode film, and the common electrode 28 is made of a second transparent electrode film. The first image signal terminal 36α1, the fourth image signal terminal 36α4, and the first dummy terminal 36ε1 are made of at least one of a portion of the first metal film different from the gate electrode 24A, a portion of the second metal film different from the source electrode 24B and the drain electrode 24C, a portion of the third metal film different from the touch wiring 30, a portion of the first transparent electrode film different from the pixel electrode and a portion of the second transparent electrode film different from the common electrode 28. The second lead-out wiring 37B, the third lead-out wiring 37C, and the fourth lead-out wiring 37D, which are the first wirings, are made of at least one of a portion of the first metal film different from the gate electrode 24A, a portion of the second metal film different from the source electrode 24B and the drain electrode 24C, and a portion of the third metal film different from the touch wiring 30.

The liquid crystal panel (display device) 11 of the present embodiment is provided with the above-described array substrate 21 and the counter substrate 20 disposed to face the array substrate 21. According to such a liquid crystal panel 11, it is possible to avoid an electrical defect in the array substrate 21, so that display failures due to the electrical defect are unlikely to occur. As a result, the display quality is improved.

### Second Embodiment

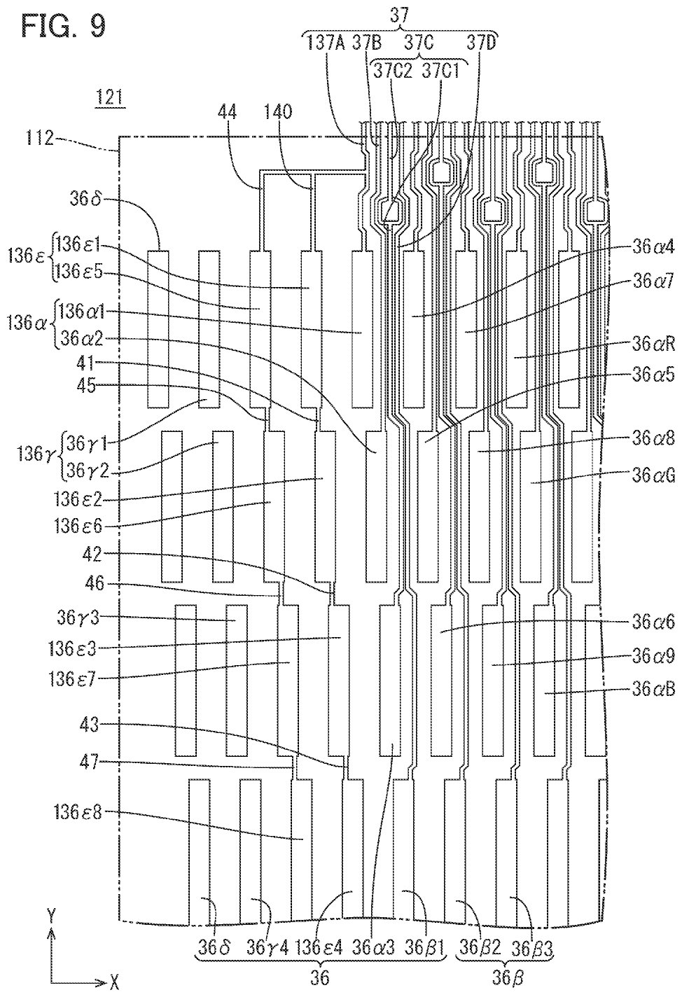

The second embodiment will be described with reference to FIG. 9. The second embodiment shows a case where a dummy terminal 136ε or the like is added. Duplicate descriptions of structure, action, and effect similar to those of the first embodiment described above will be omitted.

In the arrangement area of the driver 112 on the array substrate 121 according to the present embodiment, as shown in FIG. 9, two rows of dummy terminals 136ε are provided between an image signal terminal 136α and a common signal terminal 136γ in the X-axis direction. Specifically, the plurality of dummy terminals 136ε include four dummy terminals 136ε forming a first row disposed at positions adjacent to each other at intervals from the row of the image signal terminals 136α on the left side in FIG. 9 and four dummy terminals 136ε forming a second row disposed at positions adjacent to each other at intervals from the row of the common signal terminals 136γ on the right side in FIG. 9. The four dummy terminals 136ε forming the second row include a fifth dummy terminal 136ε5 positioned at the upper end in FIG. 9, a sixth dummy terminal 136ε6 positioned second from the upper end, a seventh dummy terminal 136ε7 positioned third from the upper end, and an eighth dummy terminal 136ε8 positioned fourth from the upper end. The four dummy terminals 136ε forming the first row include a first dummy terminal 136ε1, a second dummy terminal 136ε2, a third dummy terminal 136ε3, and a fourth dummy terminal 136ε4.

The array substrate 121 is provided with a fifth connection wiring 44 connected to the fifth dummy terminal 136ε5 and a first connection wiring 140. The fifth connection wiring 44 is indirectly connected to a first image signal terminal 136α1 via the first connection wiring 140 and a first lead-out wiring 137A. The fifth connection wiring 44 is made of the same second metal film as those of the first connection wiring 140 and the second terminal configuration portion 36B (refer to FIG. 6). Therefore, the fifth connection wiring 44 is directly connected to the second terminal configuration portion 36B and the first connection wiring 140, which constitute the fifth dummy terminal 136ε5 to be connected, without a contact hole or the like interposed therebetween. The first dummy terminal 136ε1 and the fifth dummy terminal 136ε5 are kept at the same potential as the first image signal terminal 136α1 by the first connection wiring 140 and the fifth connection wiring 44, although signal is not input from the dummy bump 39σ of the driver 112 (refer to FIG. 6). According to such a configuration, even in a case where the first image signal terminal 136α1 and the first dummy terminal 136ε1 are short-circuited, or the first dummy terminal 136ε1 and the fifth dummy terminal 136ε5 are short-circuited due to peeling of the gate insulating film 21F1, the first interlayer insulating film 21F2 and the second interlayer insulating film 21F3 (refer to FIG. 6), or electromigration of the first image signal terminal 136α1 and the first dummy terminal 136ε1, it is possible to avoid an electrical defect in the array substrate 121 due to the short circuit.

The array substrate 121 is provided with a sixth connection wiring 45 connected to the fifth dummy terminal 136ε5 and the sixth dummy terminal 136ε6, a seventh connection wiring 46 connected to the sixth dummy terminal 136ε6 and the seventh dummy terminal 136ε7, and an eighth connection wiring 47 connected to the seventh dummy terminal 136ε7 and the eighth dummy terminal 136ε8. The sixth connection wiring 45, the seventh connection wiring 46, and the eighth connection wiring 47 are made of the same second metal film as that of the second terminal configuration portion 36B (refer to FIG. 6). Therefore, the sixth connection wiring 45, the seventh connection wiring 46, and the eighth connection wiring 47 are directly connected to each of the second terminal configuration portions 36B, which constitute the fifth dummy terminal 136ε5, the sixth dummy terminal 136ε6, the seventh dummy terminal 136ε7, and the eighth dummy terminal 136ε8 to be connected, without a contact hole or the like interposed therebetween. According to such a configuration, the dummy terminals 136ε1 to 136ε4 in the first row and the dummy terminals 136ε5 to 136ε8 in the second row are brought to the same potential as that of the first image signal terminal 136α1. Therefore, even in a case where the fifth dummy terminal 136ε5 and the sixth dummy terminal 136ε6 are short-circuited, the sixth dummy terminal 136ε6 and the seventh dummy terminal 136ε7 are short-circuited, or the seventh dummy terminal 136ε7 and the eighth dummy terminal 136ε8 are short-circuited due to peeling of the gate insulating film 21F1, the first interlayer insulating film 21F2, and the second interlayer insulating film 21F3 (refer to FIG. 6), it is possible to avoid an electrical defect in the array substrate 121 due to the short circuit.

### Third Embodiment

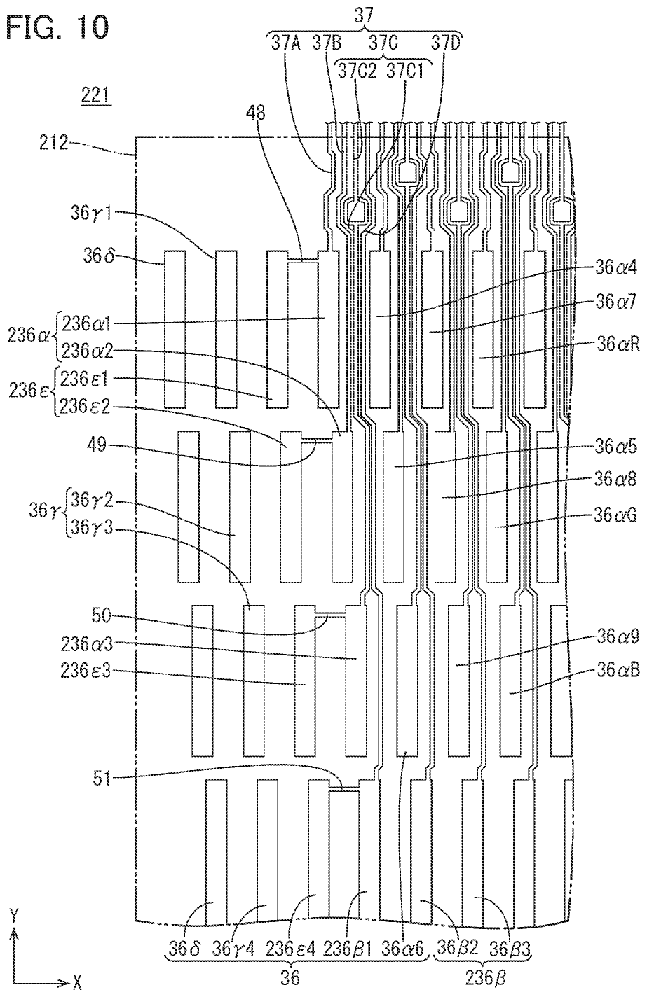

The third embodiment will be described with reference to FIG. 10. The third embodiment shows a case where a connection aspect between a dummy terminal 236ε and an image signal terminal 236α is changed from the first embodiment described above. Duplicate descriptions of structure, action, and effect similar to those of the first embodiment described above will be omitted.

In the arrangement area of the driver 212 on the array substrate 221 according to the present embodiment, as shown in FIG. 10, a ninth connection wiring (second wiring) 48 connected to a first dummy terminal 236ε1 and a first image signal terminal 236α1 is provided. The ninth connection wiring 48 extends along the X-axis direction and is connected to each of the upper end portions of the first dummy terminal 236ε1 and the first image signal terminal 236α1 in FIG. 10. The ninth connection wiring 48 is made of the same second metal film as that of the second terminal configuration portion 36B (refer to FIG. 6). Therefore, the ninth connection wiring 48 is directly connected to each of the second terminal configuration portions 36B, which constitutes the first dummy terminal 236ε1 and the first image signal terminal 236α1 to be connected, without a contact hole or the like interposed therebetween. The first dummy terminal 236ε1 and the first image signal terminal 236α1 are brought to the same potential by the ninth connection wiring 48. Therefore, even in a case where the first dummy terminal 236ε1 and the first image signal terminal 236α1 are short-circuited due to peeling of the gate insulating film 21F1, the first interlayer insulating film 21F2, and the second interlayer insulating film 21F3 (refer to FIG. 6), it is possible to avoid an electrical defect in the array substrate 221 due to the short circuit.

In the arrangement area of the driver 212 on the array substrate 221, a tenth connection wiring (fourth wiring) 49 connected to a second dummy terminal 236ε2 and a second image signal terminal 236α2 is provided. The tenth connection wiring 49 extends along the X-axis direction and is connected to each of the upper end portions of the second dummy terminal 236ε2 and the second image signal terminal 236α2 in FIG. 10. The tenth connection wiring 49 is made of the same second metal film as that of the second terminal configuration portion 36B (refer to FIG. 6). Therefore, the tenth connection wiring 49 is directly connected to each of the second terminal configuration portions 36B, which constitutes the second dummy terminal 236ε2 and the second image signal terminal 236α2 to be connected, without a contact hole or the like interposed therebetween. The second image signal terminal 236α2 and the second dummy terminal 236ε2 are brought to the same potential by the tenth connection wiring 49. Therefore, even in a case where the second image signal terminal 236α2 and the second dummy terminal 236ε2 are short-circuited due to peeling of the gate insulating film 21F1, the first interlayer insulating film 21F2, and the second interlayer insulating film 21F3, it is possible to avoid an electrical defect in the array substrate 221 due to the short circuit.

In the arrangement area of the driver 212 on the array substrate 221, an eleventh connection wiring 50 connected to a third dummy terminal 236ε3 and a third image signal terminal 236α3, and a twelfth connection wiring 51 connected to a fourth dummy terminal 236ε4 and a first touch signal terminal 236β1 are provided. The eleventh connection wiring 50 and the twelfth connection wiring 51 are made of the same second metal film as that of the second terminal configuration portion 36B (refer to FIG. 6). Therefore, the eleventh connection wiring 50 and the twelfth connection wiring 51 are directly connected to each of the second terminal configuration portions 36B, which constitutes the third dummy terminal 236ε3 to be connected, the third image signal terminal 236α3, the fourth dummy terminal 236ε4, and the first touch signal terminal 236β1, without a contact hole or the like interposed therebetween. The third image signal terminal 236α3 and the third dummy terminal 236ε3 are brought to the same potential by the eleventh connection wiring 50, and the first touch signal terminal 236β1 and the fourth dummy terminal 236ε4 are brought to the same potential by the twelfth connection wiring 51. Therefore, even in a case where the third image signal terminal 236α3 and the third dummy terminal 236ε3 are short-circuited, or the first touch signal terminal 236β1 and the fourth dummy terminal 236ε4 are short-circuited due to peeling of the gate insulating film 21F1, the first interlayer insulating film 21F2, and the second interlayer insulating film 21F3, it is possible to avoid an electrical defect in the array substrate 221 due to the short circuit.

As described above, according to the present embodiment, the tenth connection wiring (fourth wiring) 49 that connects the second image signal terminal 236α2 and the second dummy terminal 236ε2 is provided. The second image signal terminal 236α2 and the second dummy terminal 236ε2 are brought to the same potential by the tenth connection wiring 49. Therefore, even in a case where the second image signal terminal 236α2 and the second dummy terminal 236ε2 are short-circuited due to peeling of the gate insulating film 21F1, the first interlayer insulating film 21F2, and the second interlayer insulating film 21F3, which are insulating portions, it is possible to avoid an electrical defect in the array substrate 221 due to the short circuit.

### Fourth Embodiment

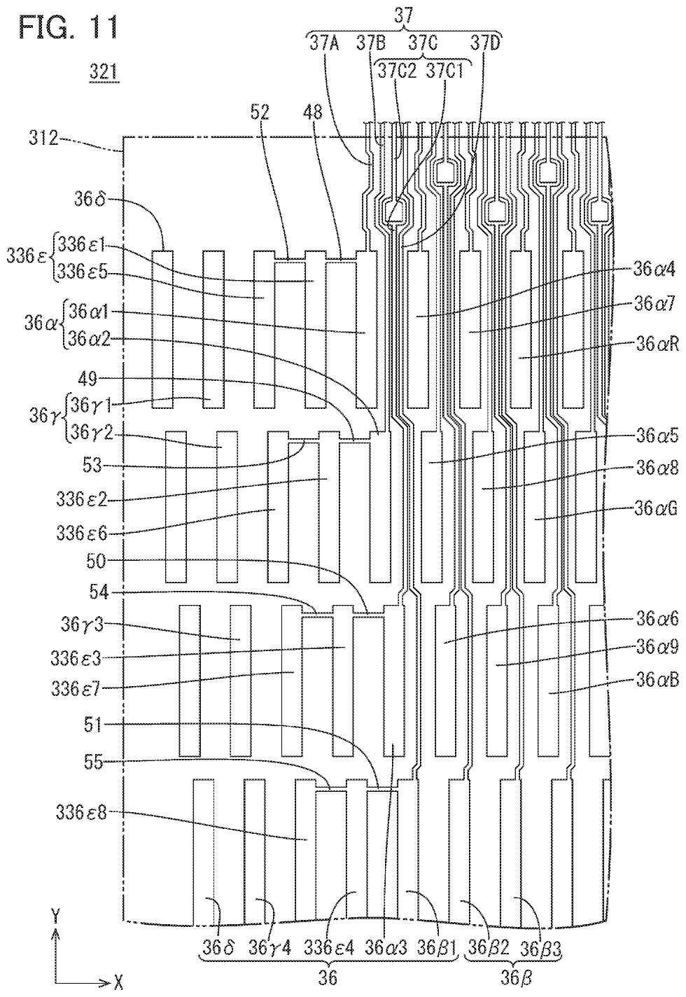

The fourth embodiment will be described with reference to FIG. 11. The fourth embodiment shows a case where a dummy terminal 336ε or the like is added from the third embodiment described above. Duplicate descriptions of structure, action, and effect similar to those of the second and third embodiments described above will be omitted.

In the arrangement area of the driver 312 on the array substrate 321 according to the present embodiment, as shown in FIG. 11, two rows of dummy terminals 336ε are provided, similarly to the second embodiment described above. The two rows of dummy terminals 336ε are as described in the second embodiment, and duplicate descriptions will be omitted.

In the arrangement area of the driver 312 on the array substrate 321, a thirteenth connection wiring 52 connected to a fifth dummy terminal 336ε5 and a first dummy terminal 336ε1, a fourteenth connection wiring 53 connected to a sixth dummy terminal 336ε6 and a second dummy terminal 336ε2, a fifteenth connection wiring 54 connected to a seventh dummy terminal 336ε7 and a third dummy terminal 336ε3, and a sixteenth connection wiring 55 connected to an eighth dummy terminal 336ε8 and a fourth dummy terminal 336ε4 are provided. The thirteenth connection wiring 52, the fourteenth connection wiring 53, the fifteenth connection wiring 54, and the sixteenth connection wiring 55 are made of the same second metal film as that of the second terminal configuration portion 36B (refer to FIG. 6). Therefore, the thirteenth connection wiring 52, the fourteenth connection wiring 53, the fifteenth connection wiring 54, and the sixteenth connection wiring 55 are directly connected to each of the second terminal configuration portions 36B, which constitutes each of the dummy terminals 336ε1 to 336ε8 to be connected, without a contact hole or the like interposed therebetween. The fifth dummy terminal 336ε5 and the first dummy terminal 336ε1 are brought to the same potential by the thirteenth connection wiring 52, the sixth dummy terminal 336ε6 and the second dummy terminal 336ε2 are brought to the same potential by the fourteenth connection wiring 53, the seventh dummy terminal 336ε7 and the third dummy terminal 336ε3 are brought to the same potential by the fifteenth connection wiring 54, and the eighth dummy terminal 336ε8 and the fourth dummy terminal 336ε4 are brought to the same potential by the sixteenth connection wiring 55. Therefore, even in a case where the fifth dummy terminal 336ε5 and the first dummy terminal 336ε1 are short-circuited, the sixth dummy terminal 336ε6 and the second dummy terminal 336ε2 are short-circuited, the seventh dummy terminal 336ε7 and the third dummy terminal 336ε3 are short-circuited, or the eighth dummy terminal 336ε8 and the fourth dummy terminal 336ε4 are short-circuited due to peeling of the gate insulating film 21F1, the first interlayer insulating film 21F2, and the second interlayer insulating film 21F3, it is possible to avoid an electrical defect in the array substrate 321 due to the short circuit.

### Fifth Embodiment

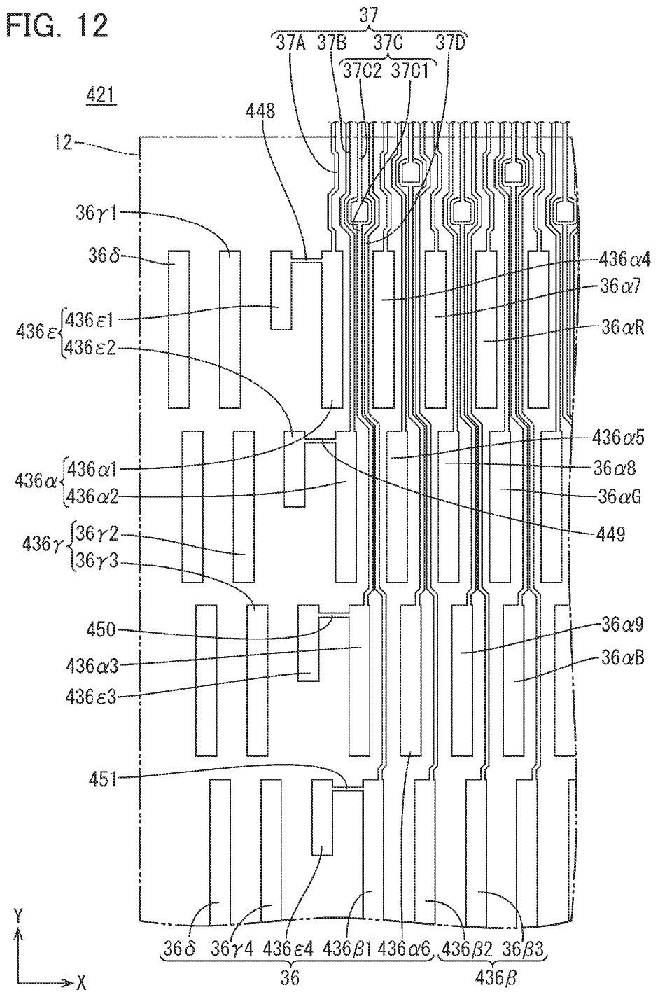

The fifth embodiment will be described with reference to FIG. 12. The fifth embodiment shows a case where a configuration of a dummy terminal 436ε is changed from the third embodiment described above. Duplicate descriptions of structure, action, and effect similar to those of the third embodiment described above will be omitted.

As shown in FIG. 12, the dummy terminal 436ε according to the present embodiment is smaller in dimension in the Y-axis direction than those of an image signal terminal 436α, a touch signal terminal 436β, a common signal terminal 436γ, and a ground signal terminal 436σ. The dummy terminal 436ε is disposed such that the upper end position in FIG. 12 is aligned with each of the upper end positions in FIG. 12 of the image signal terminal 436α, the first touch signal terminal 436β1, and the common signal terminal 436γ adjacent to each other in the X-axis direction. Therefore, an interval between each two dummy terminals 436ε disposed side by side in the Y-axis direction is longer than an interval between each two image signal terminals 436α disposed side by side in the Y-axis direction, an interval between each two common signal terminals 436γ disposed side by side in the Y-axis direction, or an interval between the image signal terminal 436α and the touch signal terminal 436β disposed side by side in the Y-axis direction. Specifically, the interval between the first dummy terminal 436ε1 and the second dummy terminal 436ε2 in the Y-axis direction is longer than any of the interval between the first image signal terminal 436α1 and the second image signal terminal 436α2 in the Y-axis direction, and the interval between the fourth image signal terminal 436α4 and the fifth image signal terminal 436α5 in the Y-axis direction. Similarly, the interval between the second dummy terminal 436ε2 and the third dummy terminal 436ε3 in the Y-axis direction is longer than any of the interval between the second image signal terminal 436α2 and the third image signal terminal 436α3 in the Y-axis direction, and the interval between the fifth image signal terminal 436α5 and the sixth image signal terminal 436α6 in the Y-axis direction. Similarly, the interval between the third dummy terminal 436ε3 and the fourth dummy terminal 436ε4 in the Y-axis direction is longer than any of the interval between the third image signal terminal 436α3 and the first touch signal terminal 436β1 in the Y-axis direction, and the interval in the Y-axis direction between the sixth image signal terminal 436α6 and the second touch signal terminal 436β2 in the Y-axis direction.

The first dummy terminal 436ε1 is brought to the same potential as that of the first image signal terminal 436α1 by the ninth connection wiring (second wiring) 448. The second dummy terminal 436ε2 is brought to the same potential as that of the second image signal terminal 436α2 by the tenth connection wiring 449. The third dummy terminal 436ε3 is brought to the same potential as that of the third image signal terminal 436α3 by the eleventh connection wiring 450. The fourth dummy terminal 436ε4 is brought to the same potential as that of the first touch signal terminal 436β1 by the twelfth connection wiring 451. Since the first dummy terminal 436ε1, the second dummy terminal 436ε2, the third dummy terminal 436ε3, and the fourth dummy terminal 436ε4 are at different potentials from each other, when the first dummy terminal 436ε1 and the second dummy terminal 436ε2 are short-circuited, the second dummy terminal 436ε2 and the third dummy terminal 436ε3 are short-circuited, or the third dummy terminal 436ε3 and the fourth dummy terminal 436ε4 are short-circuited, there is a possibility that an electrical defect may occur in the array substrate 421. In that respect, since the interval between each two dummy terminals 436ε disposed side by side in the Y-axis direction is longer than the interval between each two image signal terminals 436α disposed side by side in the Y-axis direction, the interval between each two common signal terminals 436γ disposed side by side in the Y-axis direction, or the interval between the image signal terminal 436α and the touch signal terminal 436β disposed side by side in the Y-axis direction, a situation in which the first dummy terminal 436ε1 and the second dummy terminal 436ε2 are short-circuited, the second dummy terminal 436ε2 and the third dummy terminal 436ε3 are short-circuited, or the third dummy terminal 436ε3 and the fourth dummy terminal 436ε4 are short-circuited due to peeling of the gate insulating film 21F1, the first interlayer insulating film 21F2, and the second interlayer insulating film 21F3 (refer to FIG. 6) is unlikely to occur. As a result, an electrical defect is unlikely to occur in the array substrate 421.

As described above, according to the present embodiment, the second dummy terminal 436ε2 is disposed at a position where the interval between the second dummy terminal 436ε2 and the first dummy terminal 436ε1 in the second direction is longer than any of the interval between the first image signal terminal 436α1 and the second image signal terminal 436α2 in the second direction, and the interval between the fourth image signal terminal 436α4 and the fifth image signal terminal 436α5 in the second direction. The first dummy terminal 436ε1 is brought to the same potential as that of the first image signal terminal 436α1 by the ninth connection wiring 448. The second dummy terminal 436ε2 is brought to the same potential as that of the second image signal terminal 436α2 by the tenth connection wiring 449. Since the first dummy terminal 436ε1 and the second dummy terminal 436ε2 are at different potentials, when the first dummy terminal 436ε1 and the second dummy terminal 436ε2 are short-circuited, there is a possibility that an electrical defect may occur in the array substrate 421. In that respect, since the interval between the first dummy terminal 436ε1 and the second dummy terminal 436ε2 in the second direction is longer than any of the interval between the first image signal terminal 436α1 and the second image signal terminal 436α2 in the second direction, and the interval between the fourth image signal terminal 436α4 and the fifth image signal terminal 436α5 in the second direction, a situation in which the first dummy terminal 436ε1 and the second dummy terminal 436ε2 are short-circuited due to peeling of the gate insulating film 21F1, the first interlayer insulating film 21F2, and the second interlayer insulating film 21F3, which are insulating portions, is unlikely to occur. As a result, an electrical defect is unlikely to occur in the array substrate 421.

### Sixth Embodiment

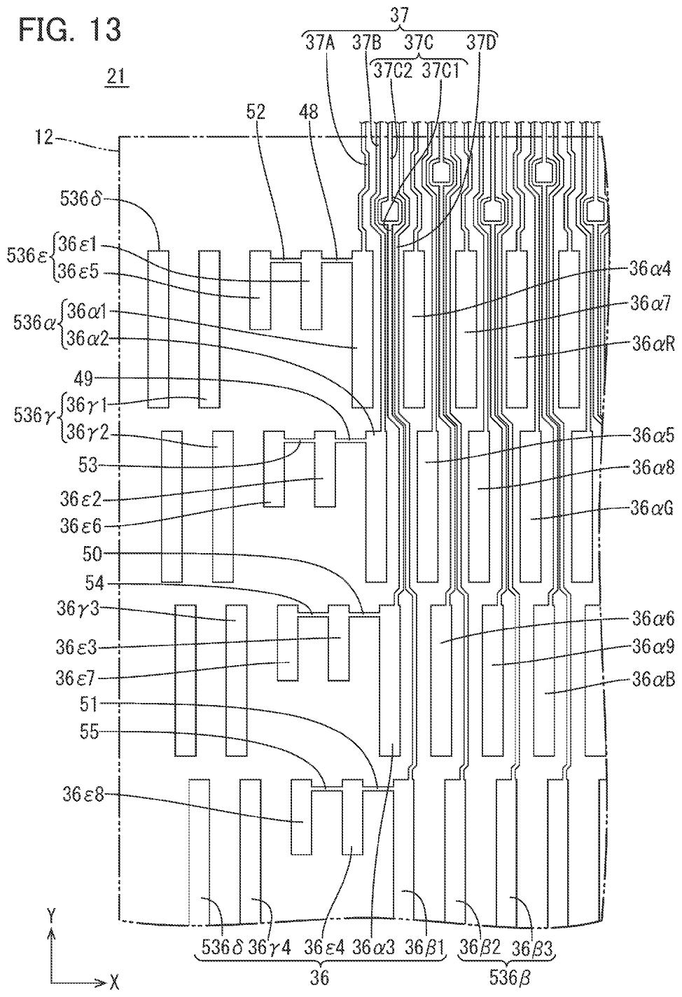

The sixth embodiment will be described with reference to FIG. 13. The sixth embodiment shows a case where a configuration of a dummy terminal 536ε is changed from the fourth embodiment described above. Duplicate descriptions of the structure, action, and effect similar to those of the fourth embodiment described above will be omitted.

As shown in FIG. 13, the dummy terminal 536ε according to the present embodiment s smaller in dimension in the Y-axis direction than those of an image signal terminal 536α, a touch signal terminal 5361, a common signal terminal 536γ, and a ground signal terminal 536σ, similarly to the fifth embodiment described above. An interval between each two dummy terminals 536ε disposed side by side in the Y-axis direction is longer than an interval between each two image signal terminals 536α disposed side by side in the Y-axis direction, an interval between each two common signal terminals 536γ disposed side by side in the Y-axis direction, or an interval between the image signal terminal 536α and the touch signal terminal 536β disposed side by side in the Y-axis direction. With the above configuration, it is possible to obtain the same action and effect as those of the fourth and fifth embodiments described above.

### Seventh Embodiment

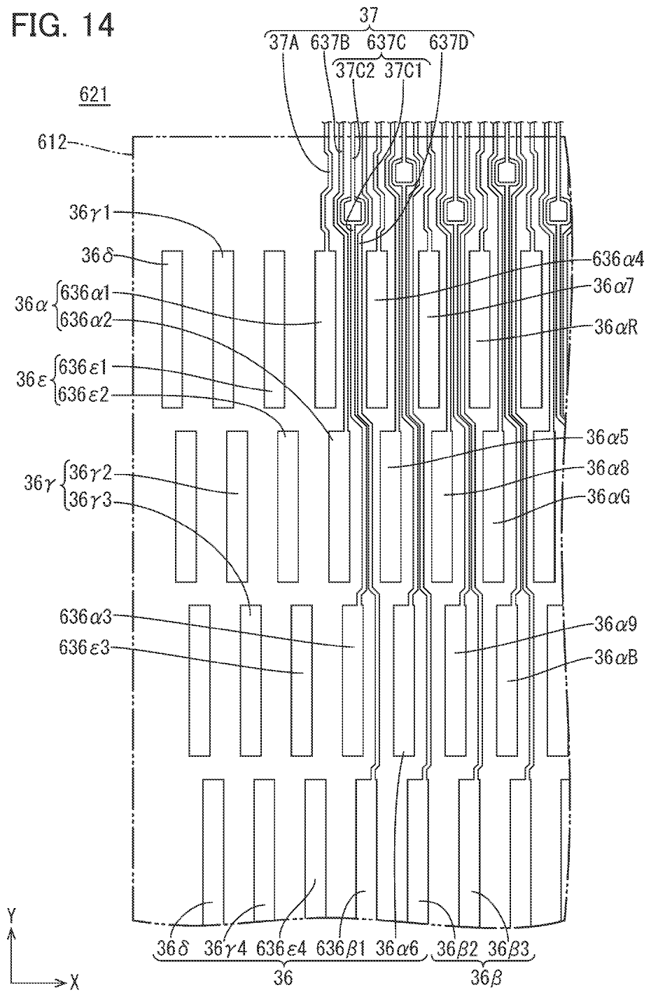

The seventh embodiment will be described with reference to FIG. 14. The seventh embodiment shows a case where each of the connection wirings 40 to 43 described in the first embodiment described above is removed. Duplicate descriptions of structure, action, and effect similar to those of the first embodiment described above will be omitted.

As shown in FIG. 14, each of the connection wirings 40 to 43 (refer to FIG. 5) described in the first embodiment is not formed in the arrangement area of the driver 612 on the array substrate 621 according to the present embodiment. Therefore, in the present embodiment, each of the dummy terminals 636ε1 to 636ε4 is electrically separated from other wirings or terminals provided on the array substrate 621 and isolated. Although each of the dummy bumps 390 (refer to FIG. 6) provided in the driver 612 is electrically connected to each of the dummy terminals 636ε1 to 636ε4, no signal (potential) is supplied from the driver 612. Therefore, even in a case where the first image signal terminal 636α1 and the first dummy terminal 636ε1 are short-circuited due to peeling of the gate insulating film 21F1, the first interlayer insulating film 21F2, and the second interlayer insulating film 21F3, it is possible to avoid an electrical defect in the array substrate 621 due to the short circuit. Even in a case where the second image signal terminal 636α2 and the second dummy terminal 636ε2 are short-circuited, the third image signal terminal 636α3 and the third dummy terminal 636ε3 are short-circuited, or the first touch signal terminal 636β1 and the fourth dummy terminal 636ε4 are short-circuited, it is possible to avoid an electrical defect in the array substrate 621 due to the short circuit.

As described above, the array substrate 621 according to the present embodiment includes the first image signal terminal 636α1, the fourth image signal terminal 636α4 disposed side by side at intervals from the first image signal terminal 636α1 in the first direction, the first dummy terminal 636ε1 disposed side by side at intervals in the first direction on a side opposite to the fourth image signal terminal 636α4 from the first image signal terminal 636α1, the second lead-out wiring 637B, the third lead-out wiring 637C, and the fourth lead-out wiring 637D, which are first wirings, positioned between the first image signal terminal 636α1 and the fourth image signal terminal 636α4, and extending along the second direction intersecting the first direction, and the gate insulating film 21F1, the first interlayer insulating film 21F2, and the second interlayer insulating film 21F3, which are insulating portions (refer to FIG. 6), disposed on the upper layer side of the first image signal terminal 636α1, the fourth image signal terminal 636α4, the first dummy terminal 636ε1, and the second lead-out wiring 637B, the third lead-out wiring 637C, and the fourth lead-out wiring 637D, which are first wirings, in which the first dummy terminal 636ε1 is disposed at a position where the interval between the first dummy terminal 636ε1 and the first image signal terminal 636α1 is longer than any of the interval between the second lead-out wiring 637B, the third lead-out wiring 637C, and the fourth lead-out wiring 637D, which are the first wirings, and the first image signal terminal 636α1, and the interval between the second lead-out wiring 637B, the third lead-out wiring 637C, and the fourth lead-out wiring 637D, which are the first wirings, and the fourth image signal terminal 636α4, the driver 612 is mounted on the array substrate 621 at a position overlapping with at least the first image signal terminal 636α1, the fourth image signal terminal 636α4, and the first dummy terminal 636ε1, and the potential is supplied from the driver 612 to the first image signal terminal 636α1 and the fourth image signal terminal 636α4, and the potential is not supplied from the driver 612 to the first dummy terminal 636ε1.

Since the interval between the first dummy terminal 636ε1 and the first image signal terminal 636α1 is longer than any of the interval between the second lead-out wiring 637B, the third lead-out wiring 637C, and the fourth lead-out wiring 637D, which are the first wirings, and the first image signal terminal 636α1, and the interval between the second lead-out wiring 637B, the third lead-out wiring 637C, and the fourth lead-out wiring 637D, which are the first wirings, and the fourth image signal terminal 636α4, for example, a situation in which the first dummy terminal 636ε1 and the first image signal terminal 636α1 are short-circuited is unlikely to occur during the manufacture of the array substrate 621. In such a configuration, when the gate insulating film 21F1, the first interlayer insulating film 21F2, and the second interlayer insulating film 21F3, which are the insulating portions, thermally expand and thermally contract as the temperature environment of the array substrate 621 changes, among the gate insulating film 21F1, the first interlayer insulating film 21F2, and the second interlayer insulating film 21F3, which are insulating portions, a large stress due to expansion and contraction acts on the portion existing between the first dummy terminal 636ε1 and the first image signal terminal 636α1, and peeling is likely to occurs, compared to a portion existing between the second lead-out wiring 637B, the third lead-out wiring 637C, and the fourth lead-out wiring 637D, which are the first wirings, and the first image signal terminal 636α1, or a portion existing between the second lead-out wiring 637B, the third lead-out wiring 637C, and the fourth lead-out wiring 637D, which are the first wirings, and the fourth image signal terminal 636α4. Among the gate insulating film 21F1, the first interlayer insulating film 21F2, and the second interlayer insulating film 21F3, which are insulating portions, when the portion existing between the first dummy terminal 636ε1 and the first image signal terminal 636α1 is peeled off, the first image signal terminal 636α1 and the first dummy terminal 636ε1 may be short-circuited. In this respect, since the potential is supplied from the driver 612 to the first image signal terminal 636α, whereas the potential is not supplied from the driver 612 to the first dummy terminal 636ε1, even in a case where the first image signal terminal 636α1 and the first dummy terminal 636ε1 are short-circuited due to peeling of the gate insulating film 21F1, the first interlayer insulating film 21F2, and the second interlayer insulating film 21F3, which are insulating portions, it is possible to avoid an electrical defect in the array substrate 621 due to the short circuit.

### Eighth Embodiment

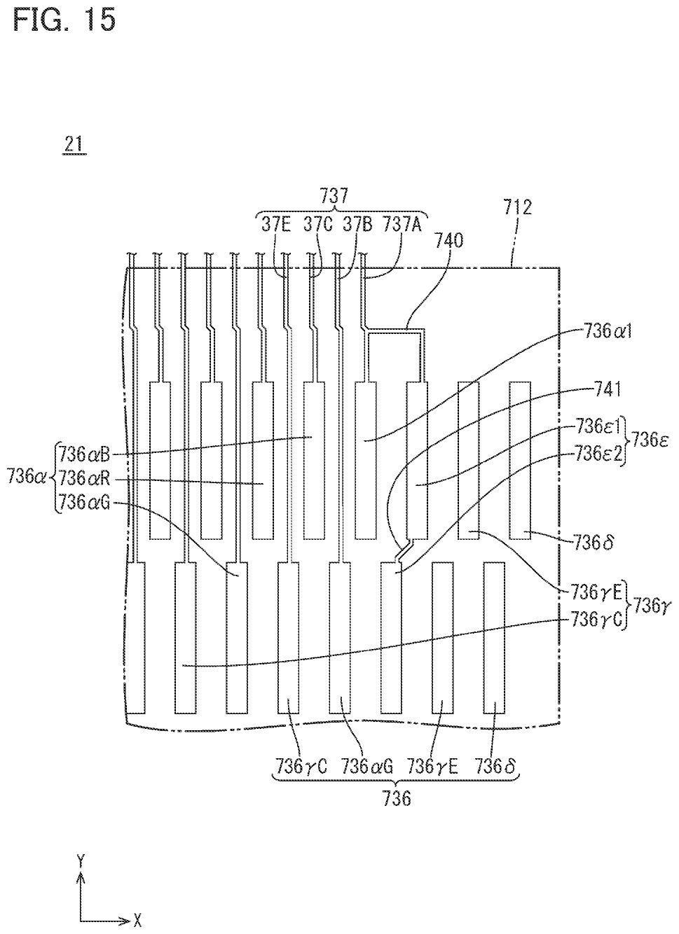

The eighth embodiment will be described with reference to FIG. 15. The eighth embodiment shows a case where the arrangement of terminals 736 is changed from the first embodiment described above. Duplicate descriptions of structure, action, and effect similar to those of the first embodiment described above will be omitted.

As shown in FIG. 15, the terminals 736 according to the present embodiment are arranged side by side two by two in the Y-axis direction in the arrangement area of the driver 712. In the present embodiment, a plurality of terminals 736 includes an image signal terminal 736α, a common signal terminal 736γ, a ground signal terminal 736σ, and a dummy terminal 736ε, but does not include the touch signal terminal 36β (refer to FIG. 5) described in the first to seventh embodiments. Hereinafter, a specific arrangement of the plurality of terminals 736 will be described.

An image signal terminal 736α and a central side common signal terminal 736γC included in the common signal terminal 736γ are disposed in the central portion in the X-axis direction in the arrangement area of the driver 712. A blue image signal terminal 736αB and a red image signal terminal 736αR included in the image signal terminal 736α are alternately disposed side by side in the X-axis direction on the upper side shown in FIG. 14. A green image signal terminal 736αG and the central side common signal terminal 736γC are alternately disposed side by side in the X-axis direction on the lower side shown in FIG. 14. The lead-out wiring 737 includes a fifth lead-out wiring 37E connected to the central side common signal terminal 736γC. An end side common signal terminal 736γE included in the common signal terminal 736γ, a ground signal terminal 736σ, and a dummy terminal 736ε are disposed in an end side portion in the X-axis direction in the arrangement area of the driver 712. Two ground signal terminals 736σ are disposed side by side in the Y-axis direction at positions in the vicinity of the right end shown in FIG. 14 in the arrangement area of the driver 712. Two end side common signal terminals 736γE are disposed side by side in the Y-axis direction at positions adjacent to the ground signal terminal 736σ at intervals on the left side shown in FIG. 14 in the arrangement area of the driver 712. The dummy terminal 736ε is positioned between the image signal terminal 736α and the central side common signal terminal 736γC in the X-axis direction and the end side common signal terminal 736γE in the arrangement area of the driver 712. Two dummy terminals 736ε are disposed side by side in the Y-axis direction. Among the two dummy terminals 736ε, a first dummy terminal 736ε1 positioned on the upper side is connected to a first connection wiring 740 connected to a first lead-out wiring 737A. As a result, the first dummy terminal 736ε1 is brought to the same potential as that of the first image signal terminal 736α1. A second connection wiring 741 is connected to the first dummy terminal 736ε1 and a second dummy terminal 736ε2 positioned on the lower side. The first dummy terminal 736ε1 and the second dummy terminal 736ε2 are brought to the same potential by the second connection wiring 741.

### Ninth Embodiment

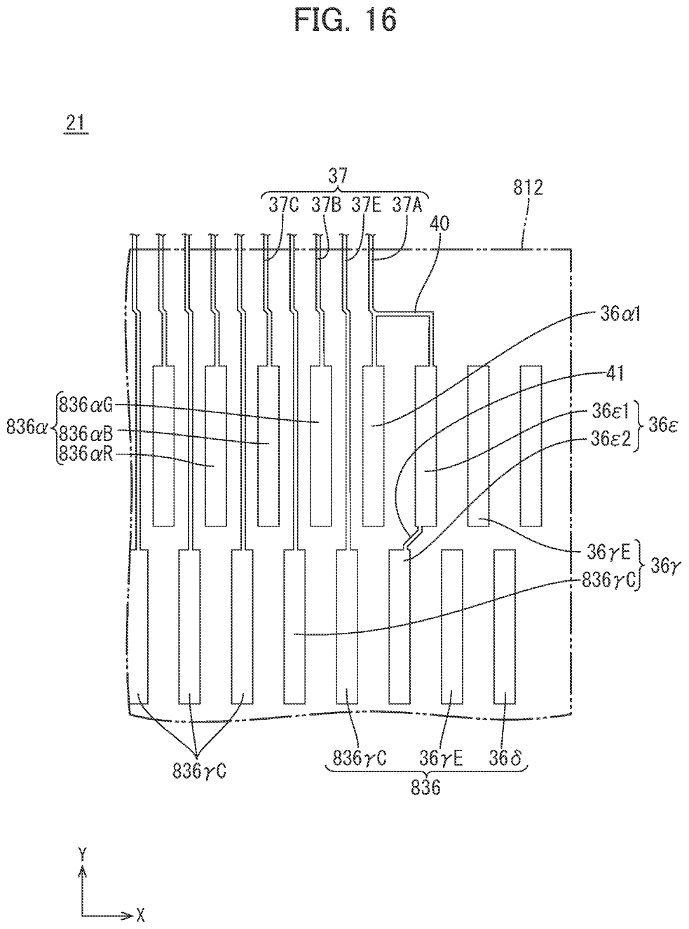

The ninth embodiment will be described with reference to FIG. 16. The ninth embodiment shows a case where the arrangement of the terminals 836 is changed from the eighth embodiment described above. Duplicate descriptions of the structure, action, and effect similar to those of the eighth embodiment described above will be omitted.

As shown in FIG. 16, in the central portion in the X-axis direction in the arrangement area of a driver 812 according to the present embodiment, an image signal terminal 836α is disposed on the upper side, and a central side common signal terminal 836γC is disposed on the lower side, respectively. A blue image signal terminal 836αB, a red image signal terminal 836αR, and a green image signal terminal 836αG included in the image signal terminal 836α are iteratively disposed side by side in a prescribed order in the X-axis direction on the upper side shown in FIG. 15. The central side common signal terminals 836γC are disposed side by side at intervals in the X-axis direction on the lower side shown in FIG. 15. In the present embodiment, the number of central side common signal terminals 836γC to be installed is increased compared to the eighth embodiment. Therefore, among the driver 812, a part of the plurality of bumps 39 (refer to FIG. 6) facing a plurality of central side common signal terminals 836γC can be used as dummies that do not share a common potential.

### Tenth Embodiment

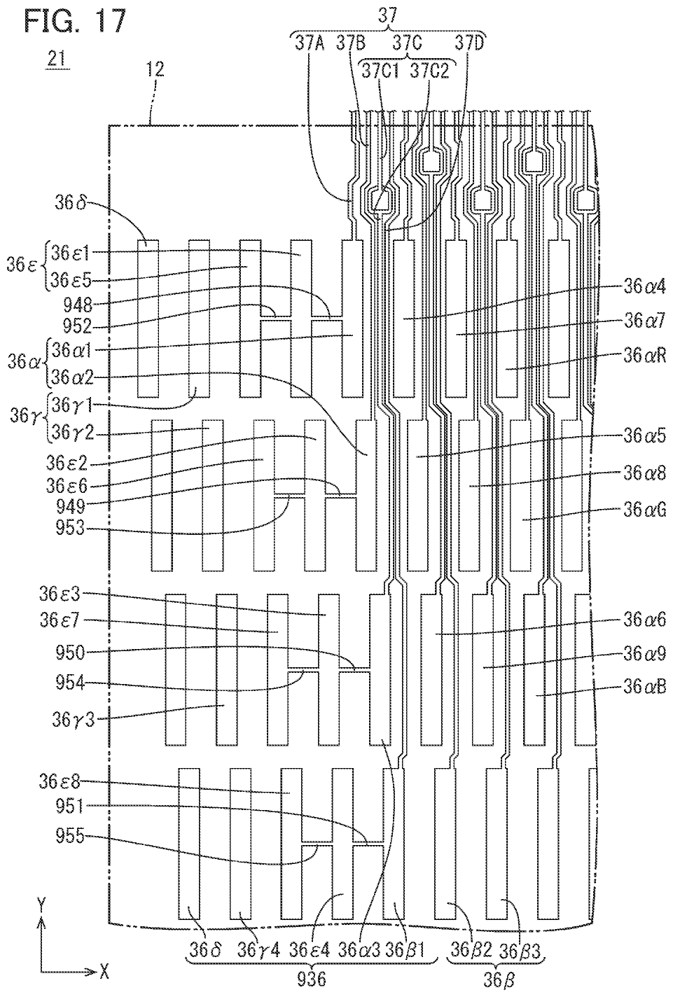

The tenth embodiment will be described with reference to FIG. 17. The tenth embodiment shows a case where the arrangement of a ninth connection wiring 948 to a sixteenth connection wiring 955 is changed from the fourth embodiment described above. Duplicate descriptions of the structure, action, and effect similar to those of the fourth embodiment described above will be omitted.

As shown in FIG. 17, a ninth connection wiring 948 to a sixteenth connection wiring 955 according to the present embodiment are connected to the vicinity of the central position in the Y-axis direction among terminals 936 to be connected. In this manner, compared to the fourth embodiment, the ninth connection wiring 948 to the sixteenth connection wiring 955 are disposed far from the terminal 936 adjacent to the terminal 936 to be connected on the upper side or the lower side shown in FIG. 16. As a result, a situation in which two vertically adjacent terminals 936 shown in FIG. 16 are short-circuited due to any of the ninth connection wiring 948 to the sixteenth connection wiring 955 is unlikely to occur. The specific arrangement of the ninth connection wiring 948 to the sixteenth connection wiring 955 in the Y-axis direction can be appropriately changed other than the illustration in FIG. 17. The configuration of the ninth connection wiring 948 to the sixteenth connection wiring 955 described in the present embodiment can also be applied to the sixth embodiment described above. The configuration of the ninth connection wiring 948 to the twelfth connection wiring 951 described in the present embodiment can also be applied to the third and fifth embodiments described above.

### Eleventh Embodiment

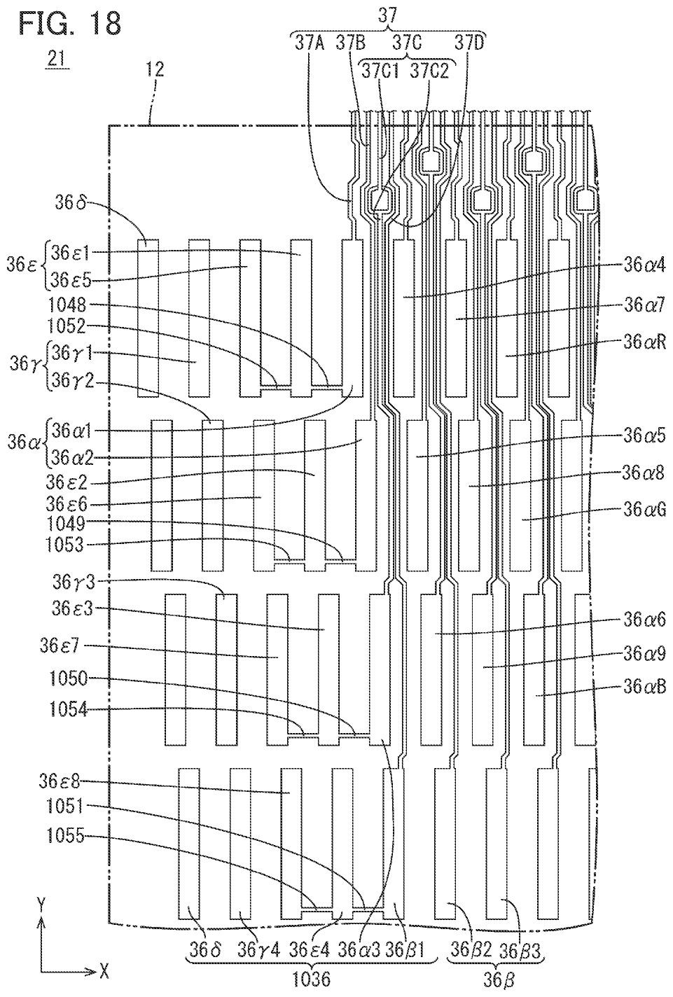

The eleventh embodiment will be described with reference to FIG. 18. The eleventh embodiment shows a case where the arrangement of a ninth connection wiring 1048 to a sixteenth connection wiring 1055 is changed from the tenth embodiment described above. Duplicate descriptions of the structure, action, and effect similar to those of the tenth embodiment described above described above will be omitted.

As shown in FIG. 18, a ninth connection wiring 1048 to a sixteenth connection wiring 1055 according to the present embodiment are connected to the vicinity of the lower end position in the Y-axis direction among terminals 1036 to be connected. The specific arrangement of the ninth connection wiring 1048 to the sixteenth connection wiring 1055 in the Y-axis direction can be appropriately changed other than the illustration in FIG. 17. The configuration of the ninth connection wiring 1048 to the sixteenth connection wiring 1055 described in the present embodiment can also be applied to the sixth embodiment described above. The configuration of the ninth connection wiring 1048 to the twelfth connection wiring 1051 described in the present embodiment can also be applied to the third and fifth embodiments described above.

### OTHER EMBODIMENTS

The technique disclosed in the present specification is not limited to the embodiments described by the above description and drawings, and for example, the following embodiments are also included in the technical scope.

(1) Signals (potentials) may be supplied from the dummy bumps 39σ of the drivers 12, 112, 212, 312, 612, 712, and 812 to the dummy terminals 36ε, 136ε, 236ε, 336ε, 436ε, 536ε, and 736ε. In that case, for example, the signals supplied from the dummy bumps 390 connected to the first dummy terminals 36ε1, 136ε1, 236ε1, 336ε1, 436ε1, 636ε1, and 736ε1 to the first dummy terminals 36ε1, 136ε1, 236ε1, 336ε1, 436ε1, 636ε1, and 736ε1 are the same as the signals supplied from the image signal bumps 39α connected to the first image signal terminals 36α1, 136α1, 236α1, 436α1, 636α1, and 736α1 to the first image signal terminals 36α1, 136α1, 236α1, 436α1, 636α1, and 736α1.

(2) In the arrangement area of the drivers 12, 112, 212, 312, 612, 712, and 812 of the array substrates 21, 121, 221, 321, 421, and 621, the ground signal terminals 36σ, 436σ, 536σ, and 736σ may be disposed between the common signal terminals 36γ, 136γ, 436γ, 536γ, and 736γ and the dummy terminals 36ε, 136ε, 236ε, 336ε, 436ε, 536ε, and 736ε in the X-axis direction. That is, the positional relationships in the X-axis direction between the ground signal terminals 36σ, 436σ, 536σ, and 736σ and the common signal terminals 36γ, 136γ, 436γ, 536γ, and 736γ may be reversed from the illustration in each drawing.

(3) The array substrates 21, 121, 221, 321, 421, and 621 may be provided with a common signal wiring connected to the common signal terminals 36γ, 136γ, 436γ, 536γ, and 736γ and a ground signal wiring connected to the ground signal terminals 36σ, 436σ, 536σ, and 736σ.

(4) The second interlayer insulating film 21F3 may be provided on the upper layer side of the fourth terminal configuration portion 36D, which constitutes the terminals 36, 736, 836, 936, and 1036. In that case, an opening is provided in the second interlayer insulating film 21F3 at a position overlapping with the fourth terminal configuration portion 36D.

(5) In above (4), the terminals 36, 736, 836, 936, and 1036 may have a fifth terminal configuration portion made of the second transparent electrode film. The fifth terminal configuration portion is connected to the fourth terminal configuration portion 36D through the opening of the second interlayer insulating film 21F3.

(6) In above (5), a third interlayer insulating film 21F4 may be provided on the upper layer side of the fifth terminal configuration portion, which constitutes the terminals 36, 736, 836, 936, and 1036. In that case, an opening is provided at a position of the third interlayer insulating film 21F4 that overlaps with the fifth terminal configuration portion.

(7) In above (4) and (5), among the terminals 36, 736, 836, 936, and 1036, the fourth terminal configuration portion 36D made of the first transparent electrode film may be omitted.

(8) Among the terminals 36, 736, 836, 936, and 1036, the third terminal configuration portion 36C made of the third metal film may be omitted.

(9) Among the terminals 36, 736, 836, 936, and 1036, the second terminal configuration portion 36B made of the second metal film may be omitted.

(10) Among the terminals 36, 736, 836, 936, and 1036, both the third terminal configuration portion 36C made of the third metal film and the second terminal configuration portion 36B made of the second metal film may be omitted.

(11) Among the terminals 36, 736, 836, 936, and 1036, the first terminal configuration portion 36A made of the first metal film may be omitted.

(12) Among the terminals 36, 736, 836, 936, and 1036, both the third terminal configuration portion 36C made of the third metal film and the first terminal configuration portion 36A made of the first metal film may be omitted.

(13) Among the terminals 36, 736, 836, 936, and 1036, both the second terminal configuration portion 36B made of the second metal film and the first terminal configuration portion 36A made of the first metal film may be omitted.

(14) Among the terminals 36, 736, 836, 936, and 1036, the fourth terminal configuration portion 36D made of the first transparent electrode film may be omitted.

(15) The arrangement intervals in the X-axis direction of the plurality of terminals 36, 736, 836, 936, and 1036 disposed side by side in the X-axis direction may not all be equal to each other.

(16) A planarizing film made of an organic material may be interposed between the first interlayer insulating film 21F2 and the third metal film.

(17) The specific number of lead-out wirings 37 and 737 disposed between the image signal terminals 36α, 136α, 236α, 436α, 536α, 736α, and 836α and the dummy terminals 36ε, 136ε, 236ε, 336ε, 436ε, 536ε, and 736ε can be changed as appropriate.

(18) The first wiring disposed between the image signal terminals 36α, 136α, 236α, 436α, 536α, 736α, and 836α and the dummy terminals 36ε, 136ε, 236ε, 336ε, 436ε, 536ε, and 736ε may be other than the lead-out wirings 37 and 737. The first wiring may not be connected to the image signal terminals 36α, 136α, 236α, 436α, 536α, 736α, and 836α and the touch signal terminals 36β, 236β, 436β, and 536β.

(19) The specific arrangement of the terminals 36, 736, 836, 936, and 1036 in the arrangement areas of the drivers 12, 112, 212, 312, 612, 712, and 812 of the array substrates 21, 121, 221, 321, 421, and 621 can be changed as appropriate. For example, an arrangement in which positions in the X-axis direction of a plurality of terminals 36, 736, 836, 936, and 1036 disposed side by side in the Y-axis direction are aligned may be provided. Alternatively, an arrangement in which the plurality of terminals 36, 736, 836, 936, and 1036 are disposed side by side three by three at intervals in the Y-axis direction may be provided. Furthermore, although the plurality of terminals 36, 736, 836, 936, and 1036 are disposed side by side at intervals in the X-axis direction, only one may be disposed in the Y-axis direction.

(20) The terminals 36, 736, 836, 936, and 1036 may not include the touch signal terminals 36β, 236β, 436β, and 536β. That is, the liquid crystal panel 11 without the touch panel function may be used. In this case, the common electrode 28 has a non-divided structure, the touch electrode 29 is not formed, and the third metal film is not formed.

The present disclosure contains subject matter related to that disclosed in Japanese Priority Patent Application JP 2022-090131 filed in the Japan Patent Office on Jun. 2, 2022, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A wiring substrate comprising:
a first terminal;
a second terminal disposed side by side at intervals from the first terminal in a first direction;
a third terminal disposed side by side at intervals from the first terminal in the first direction on a side opposite to the second terminal;
a first wiring positioned between the first terminal and the second terminal and that extends along a second direction intersecting the first direction;
a second wiring connected to the first terminal and the third terminal; and
an insulating portion disposed on an upper layer side of the first terminal, the second terminal, the third terminal, the first wiring, and the second wiring, wherein
the third terminal is disposed at a position where an interval between the third terminal and the first terminal is longer than any of an interval between the first wiring and the first terminal, and an interval between the first wiring and the second terminal.

2. The wiring substrate according to claim 1, further comprising:
a fourth terminal disposed at intervals from the first terminal in the second direction;
a fifth terminal disposed at intervals from the second terminal in the second direction and disposed side by side at intervals from the fourth terminal in the first direction; and
a sixth terminal disposed at intervals from the third terminal in the second direction and disposed side by side at intervals from the fourth terminal in the first direction on a side opposite to the fifth terminal, wherein
mounted components are mounted on positions of the wiring substrate that overlap with at least the first terminal, the second terminal, the third terminal, the fourth terminal, the fifth terminal, and the sixth terminal, and
the first terminal, the second terminal, and the third terminal are positioned closer to an end of the mounted component than the fourth terminal, the fifth terminal, and the sixth terminal.

3. The wiring substrate according to claim 2, further comprising:
a third wiring that connects the third terminal and the sixth terminal.

4. The wiring substrate according to claim 2, further comprising:
a fourth wiring that connects the fourth terminal and the sixth terminal.

5. The wiring substrate according to claim 4, wherein
the sixth terminal is disposed at a position where an interval between the sixth terminal and the third terminal in the second direction is longer than any of an interval between the first terminal and the fourth terminal in the second direction and an interval between the second terminal and the fifth terminal in the second direction.

6. A wiring substrate comprising:
a first terminal;
a second terminal disposed side by side at intervals from the first terminal in a first direction;
a third terminal disposed side by side at intervals from the first terminal in the first direction on a side opposite to the second terminal;
a first wiring positioned between the first terminal and the second terminal and that extends along a second direction intersecting the first direction; and
an insulating portion disposed on an upper layer side of the first terminal, the second terminal, the third terminal, and the first wiring, wherein
the third terminal is disposed at a position where an interval between the third terminal and the first terminal is longer than any of an interval between the first wiring and the first terminal, and an interval between the first wiring and the second terminal,
mounted components are mounted on positions of the wiring substrate that overlap with at least the first terminal, the second terminal, and the third terminal,
a potential is supplied from the mounted component to the first terminal and the second terminal, and
a potential is not supplied from the mounted component to the third terminal.

7. The wiring substrate according to claim 1, further comprising:
a thin film transistor;
a pixel electrode connected to the thin film transistor;
a common electrode disposed overlapping with the pixel electrode, and including a plurality of position detection electrodes; and
a position detection wiring connected to the position detection electrode, wherein
the thin film transistor includes a gate electrode, a semiconductor portion disposed overlapping with the gate electrode, a source electrode in contact with a part of the semiconductor portion, and a drain electrode disposed at intervals from the source electrode and in contact with the part of the semiconductor portion,
the gate electrode is made of a first metal film,
the semiconductor portion is made of a semiconductor film,
the source electrode is made of a second metal film,
the drain electrode is made of a portion of the second metal film different from the source electrode,
the position detection wiring is made of a third metal film,
the pixel electrode is made of a first transparent electrode film,
the common electrode is made of a second transparent electrode film,
the first terminal, the second terminal, and the third terminal are made of at least one of a portion of the first metal film different from the gate electrode, a portion of the second metal film different from the source electrode and the drain electrode, a portion of the third metal film different from the position detection wiring, a portion of the first transparent electrode film different from the pixel electrode, and a portion of the second transparent electrode film different from the common electrode, and
the first wiring is made of at least one of the portion of the first metal film different from the gate electrode, the portion of the second metal film different from the source electrode and the drain electrode, and the portion of the third metal film different from the position detection wiring.

8. A display device comprising:
the wiring substrate according to claim 1; and
a counter substrate disposed to face the wiring substrate.
